(19) United States
(12) Patent Application Publication
(10) Pub. No.: US 2026/0249285 A1
(43) Pub. Date: Aug. 27, 2026

(54) NMR TUBE ASSEMBLY AND FILLING METHOD THEREFOR

(71) Applicant: Norell, Inc., Morganton, NC (US)

(72) Inventors: Gregory B. Norell, Morganton, NC (US); Scott Ammalathithada, Morganton, NC (US)

(73) Assignee: Norell, Inc., Morganton, NC (US)

(21) Appl. No.: 19/537,953

(22) Filed: Feb. 12, 2026

Related U.S. Application Data
(60) Provisional application No. 63/761,297, filed on Feb. 21, 2025.

(51) Int. Cl. B01L 3/00; G01R 33/30

(52) U.S. Cl. CPC B01L 3/502; B01L 3/5021; G01R 33/307

(57) ABSTRACT

A closure for an NMR tube including a top end having a first opening, a bottom end having a second opening, a bore that extends from the first opening to the second opening. The bore has a reservoir chamber located adjacent to the first opening. The reservoir chamber has a tapered funnel section having a taper angle between 55° and 70°. The closure is configured to be coupled to the NMR tube to form an NMR tube assembly. During a filling procedure, a liquid sample received in the reservoir chamber is configured to be held in the reservoir chamber until transferred into the NMR tube by subjecting the NMR tube assembly to a centrifugal force. A tube rack containing the NMR tubes may be placed into a centrifuge and subjected to centrifugal force to transfer the liquid sample from the reservoir chamber to the tube cavity of the NMR tubes.

### CROSS-REFERENCE TO RELATED APPLICATIONS

The present application claims the benefit of priority to U.S. Provisional Patent Application Ser. No. 63/761,297, filed on Feb. 21, 2025, the entirety of which is incorporated herein by reference.

### BACKGROUND OF THE INVENTION

Nuclear Magnetic Resonance (NMR) spectroscopy is a widely used analytical technique requiring precise sample preparation to ensure accurate and reproducible results. Traditional 1.0 mm and 1.7 mm NMR tube loading methods require direct sample introduction into the tube's narrow bore (approximately 0.7 mm and 1.3 mm inner diameter, respectively). This conventional approach presents several challenges. For instance, the narrow diameter creates significant surface tension effects that resist liquid flow. In addition, air bubbles frequently form during loading, requiring careful and slow sample introduction. Furthermore, direct loading typically requires precise needle positioning and extremely steady hand movements. Sample viscosity effects compound these challenges, especially with more viscous samples. The process also typically takes several minutes per sample, creating a bottleneck in high-throughput environments.

In addition, traditional septa NMR tubes are assemblies consisting of a glass NMR tube fused to a threaded glass vial, which accepts a standard threaded septa cap. This established design presents several significant limitations, including manufacturing complexities (e.g., specialized glassblowing to permanently join the NMR tube and threaded vial), lack of automation compatibility due to the large upper diameter, and difficulties in maintaining septa integrity over multiple uses.

Furthermore, NMR spectroscopy has traditionally relied on tubes with external caps that must be manually removed and replaced for sample loading. This conventional approach creates significant bottlenecks in modern analytical environments where automation and efficiency are essential. The traditional external cap system presents multiple limitations: it requires manual handling for sample loading, risks sample contamination, offers limited protection against aggressive solvents, and fundamentally constrains the speed and reliability of automated sample handling systems.

Thus, needs exist to address the aforementioned deficiencies in existing NMR tube assemblies and systems.

### BRIEF SUMMARY OF THE INVENTION

The present invention is directed to certain improvements to NMR tube assemblies that include an NMR tube and a closure, and also relate to improvements in methods for filling such NMR tube assemblies with a liquid sample.

In one aspect, the invention may be a closure for an NMR tube, the closure comprising: a top end having a first opening; a bottom end having a second opening; a bore that extends from the first opening in the top end to the second opening in the bottom end, the bore comprising a reservoir chamber located adjacent to the first opening, the reservoir chamber comprising a tapered funnel section having a taper angle between 55° and 70°; and wherein the closure is configured to be coupled to the NMR tube to form an NMR tube assembly, and wherein a liquid sample received in the reservoir chamber is configured to be held in the reservoir chamber until transferred into the NMR tube by subjecting the NMR tube assembly to a centrifugal force.

In another aspect, the invention may be a method for loading liquid samples into NMR tubes, the method comprising: attaching one of a plurality of closures to each of a plurality of NMR tubes to form a plurality of NMR tube assemblies, each of the plurality of closures comprising a reservoir chamber; introducing a liquid sample into the reservoir chamber of each of the plurality of closures of each of the plurality of NMR tube assemblies, the liquid sample being maintained in the reservoir chamber of the closure without passively flowing into a cavity of the NMR tube to which the closure is attached; and subjecting the plurality of NMR tube assemblies to a centrifugal force to transfer the liquid sample from the reservoir chamber of the closure into the cavity of the NMR tube to which the closure is attached.

In yet another aspect, the invention may be a method for loading a liquid sample into an NMR tube, the method comprising: attaching a closure to an NMR tube to form an NMR tube assembly, the closure comprising a reservoir chamber and the NMR tube having a cavity; introducing a liquid sample into the reservoir chamber of the closure of the NMR tube assembly, the liquid sample being maintained in the reservoir chamber of the closure and being prevented from passively flowing into a cavity of the NMR tube to which the closure is attached; and subjecting the NMR tube assembly to a centrifugal force to transfer the liquid sample from the reservoir chamber of the closure into the cavity of the NMR tube.

In still another aspect, the invention may be an NMR tube system comprising: a first NMR tube comprising a first cavity having a first diameter; a second NMR tube comprising a second cavity having a second diameter that is greater than the first diameter; and a closure comprising a head portion and a sleeve portion extending from the head portion, the sleeve portion comprising an outer surface and an inner surface that defines a sleeve cavity; wherein the closure is configured to be coupled to the first NMR tube by inserting a top portion of the first NMR tube into the sleeve cavity of the sleeve portion of the closure; and wherein the closure is configured to be coupled to the second NMR tube by inserting the sleeve portion of the closure into a top portion of the second cavity of the second NMR tube.

In a further aspect, the invention may be an NMR tube assembly comprising: an NMR tube comprising an inner surface that defines a tube cavity having an open top end and a closed bottom end; a septa disposed within the tube cavity and dividing the tube cavity into a top portion located between the septa and the open top end and a bottom portion located between the septa and the closed bottom end; and a closure comprising a sleeve portion and a head portion, the sleeve portion of the closure disposed within the top portion of the tube cavity of the NMR tube to couple the closure to the NMR tube, the closure comprising a bore that extends from a top end of the closure to a bottom end of the closure to permit insertion of a filling needle through the bore of the closure and into and through the septa for introduction of a liquid sample into the bottom portion of the tube cavity.

In a still further aspect, the invention may be an NMR tube assembly comprising: an NMR tube comprising an inner surface that defines a tube cavity having an open top end and a closed bottom end, the NMR tube comprising at least one constriction; and a septa disposed within the tube cavity in engagement with the at least one constriction to lock the septa in place within the tube cavity, the septa dividing the tube cavity into a top portion located between the septa and the open top end and a bottom portion located between the septa and the closed bottom end.

In yet another aspect, the invention may be an NMR tube assembly comprising: an NMR tube having an outer surface and an inner surface that defines a tube cavity having a closed bottom end and an open top end; a closure assembly configured to be coupled to the NMR tube, the closure assembly comprising: a closure member comprising a top end, a bottom end, and a relief cavity formed into the bottom end, the relief cavity comprising a floor that is located between the bottom end and the top end and an opening in the bottom end; and a septa positioned within the relief cavity adjacent to the floor; and wherein the closure assembly is configured to be coupled to the NMR tube such that a top portion of the NMR tube is located within the relief cavity of the closure member and a top end of the NMR tube is in contact with a bottom surface of the septa.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 is a top perspective view of an NMR tube assembly in accordance with an embodiment of the present invention;

FIG. 2 is a bottom perspective view of the NMR tube assembly of FIG. 1;

FIG. 3 is an exploded front view of the NMR tube assembly of FIG. 1;

FIG. 4 is a cross-sectional view taken along line IV-IV of FIG. 3;

FIG. 5A is a cross-sectional view taken along line VA-VA of FIG. 1;

FIG. 5B is a cross-sectional view taken along line VB-VB of FIG. 1;

FIG. 6A is a cross-sectional view taken along line VA-VA of FIG. 1, including a schematic illustration of a liquid handler introducing a liquid sample into a reservoir chamber of a closure of the NMR tube assembly of FIG. 1;

FIG. 6B is a cross-sectional view taken along line VA-VA of FIG. 1, illustrating the reservoir chamber of the closure filled with the sample liquid

FIG. 7A is a perspective view of a plurality of the NMR tube assemblies of FIG. 1 positioned in a tube rack;

FIG. 7B is a schematic cross-sectional view taken along line VIIB-VIIB of FIG. 7B, and further illustrating a liquid dispensing device simultaneously introducing a liquid sample into the closure of each of the plurality of NMR tube assemblies;

FIG. 7C is a perspective view of the plurality of the NMR tube assemblies positioned in the tube rack as shown in FIG. 7A, with a liquid sample filling the reservoir chamber of the closure of each of the NMR tube assemblies;

FIG. 8 is a perspective view of the tube rack containing the NMR tube assemblies as shown in FIG. 7 located in a rotor of a centrifuge;

FIG. 9 is a perspective view of the plurality of NMR tube assemblies located in the tube rack after having been subjected to a centrifugal force such that the liquid sample has transferred from the reservoir chamber of the closure into a cavity of the NMR tube;

FIG. 10 is a top perspective view of an NMR tube assembly in accordance with another embodiment of the present invention;

FIG. 11 is a bottom perspective view of the NMR tube assembly of FIG. 10;

FIG. 12 is a front view of the NMR tube assembly of FIG. 10;

FIG. 13 is an exploded front view of the NMR tube assembly of FIG. 10;

FIG. 14 is a cross-sectional view taken along line XIV-XIV of FIG. 13;

FIG. 15A is a cross-sectional view taken along line XV-XV of FIG. 12;

FIG. 15B is the cross-sectional view of FIG. 15A, with a schematic illustration of a liquid sample being introduced into a cavity of the NMR tube of the NMR tube assembly;

FIG. 16 is a top perspective view of an NMR tube assembly in accordance with yet another embodiment of the present invention;

FIG. 17 is a bottom perspective view of the NMR tube assembly of FIG. 16;

FIG. 18 is a front view of the NMR tube assembly of FIG. 16;

FIG. 19 is an exploded front view of the NMR tube assembly of FIG. 16;

FIG. 20 is a cross-sectional view taken along line XX-XX of FIG. 10;

FIG. 21 is a front view of an NMR tube of the NMR tube assembly of FIG. 16;

FIG. 22 is a cross-sectional view taken along line;

FIG. 23 is a detail view of area XXIII of FIG. 22; and

FIG. 24 is the detail view of FIG. 23, with a schematic illustration of a liquid sample being introduced into a cavity of the NMR tube of the NMR tube assembly.

### DETAILED DESCRIPTION OF THE INVENTION

The following description of the preferred embodiment(s) is merely exemplary in nature and is in no way intended to limit the invention, its application, or uses. The description of illustrative embodiments according to principles of the present invention is intended to be read in connection with the accompanying drawings, which are to be considered part of the entire written description. In the description of embodiments of the invention disclosed herein, any reference to direction or orientation is merely intended for convenience of description and is not intended in any way to limit the scope of the present invention. Relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” and similar refer to a relationship wherein structures are secured or attached to one another either directly or indirectly through intervening structures, as well as both movable or rigid attachments or relationships, unless expressly described otherwise.

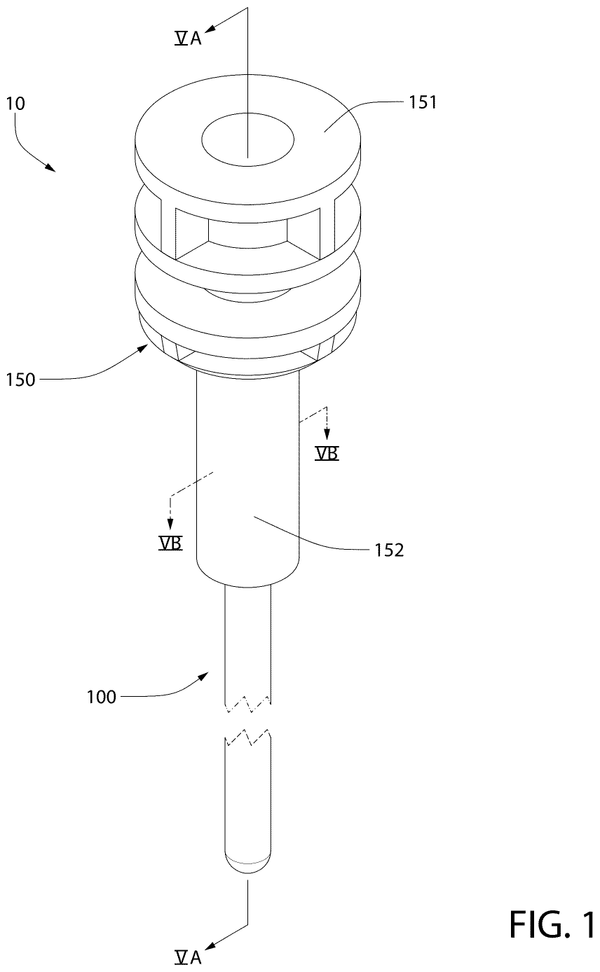

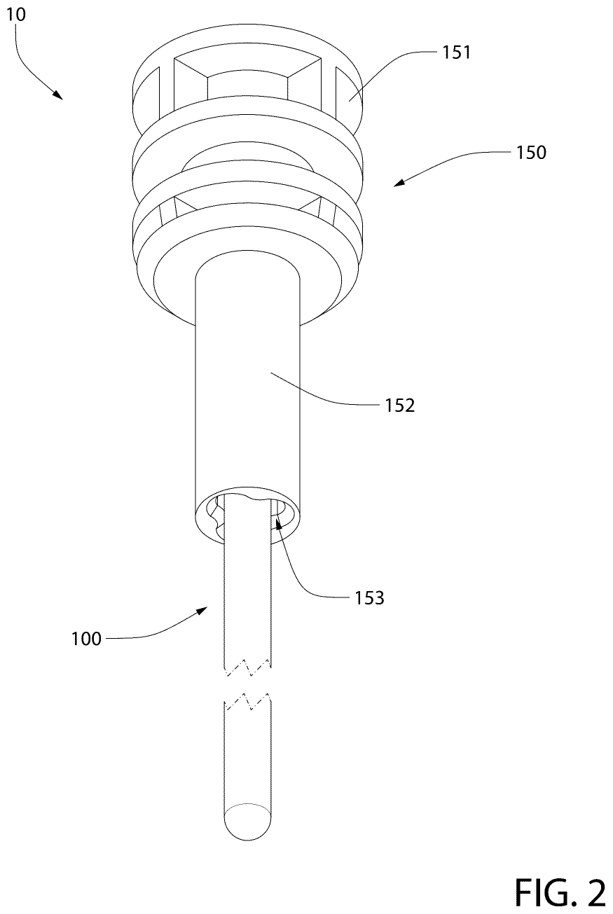

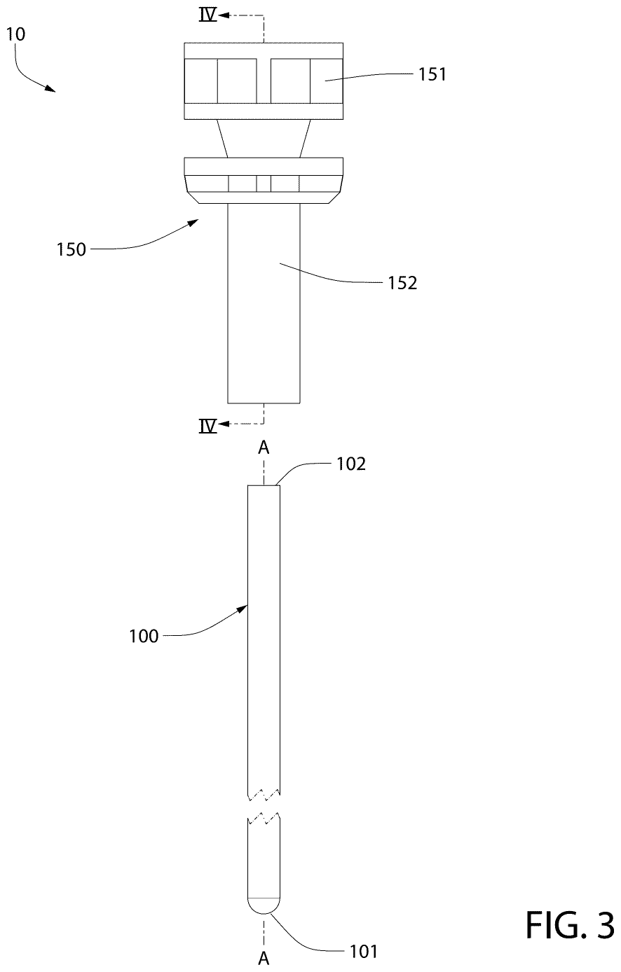

Referring to FIGS. 1-3, an NMR tube assembly 10 is illustrated in accordance with an exemplary embodiment of the present invention. The NMR tube assembly 10 generally comprises an NMR tube 100 and a closure or a closure member 150. The closure member 150 is configured to be fitted onto a top end of the NMR tube 100 via a press fit or friction fit engagement. Thus, the closure member 150 may be repeatedly attached to and detached from the NMR tube 100 by pressing the closure member 150 onto the top portion of the NMR tube 100 and pulling the closure member 150 away from the NMR tube 100.

The NMR tube 100 is formed from glass, such as borosilicate. The NMR tube 100 generally comprises a bottom end 101 and a top end 102, with the NMR tube 100 being elongated between the bottom and top ends 101, 102. The NMR tube 100 may have a longitudinal axis A-A that extends between the bottom and top ends 101, 102. As shown in later views described below, the NMR tube 100 comprises a tube cavity that is configured to receive a liquid sample.

The closure member 150 comprises a head portion 151 and a sleeve portion 152. As described in more detail below, the sleeve portion 152 is configured to receive a top portion of the NMR tube 100 when the closure member 150 is coupled to the NMR tube 100. In the exemplified embodiment, the sleeve portion 152 comprises a sleeve cavity 153 that is configured to receive a top portion of the NMR tube 100 to facilitate the attachment of the closure member 150 to the NMR tube 100. In the exemplified embodiment, the head portion 151 has a specific outer surface structure that enables the head portion 151 of the closure member 150 to be handled by a robot. That is, certain robots may be capable of gripping the head portion 151 of the closure member 150 to move the NMR tube assembly 10 to a desired location during a spectroscopy process. The attachment of the closure member 150 to the NMR tube 100 is such that when the closure member 150 is gripped either by a human user or a robot, the closure member 150 remains attached to the NMR tube due to the friction/interference between the two parts.

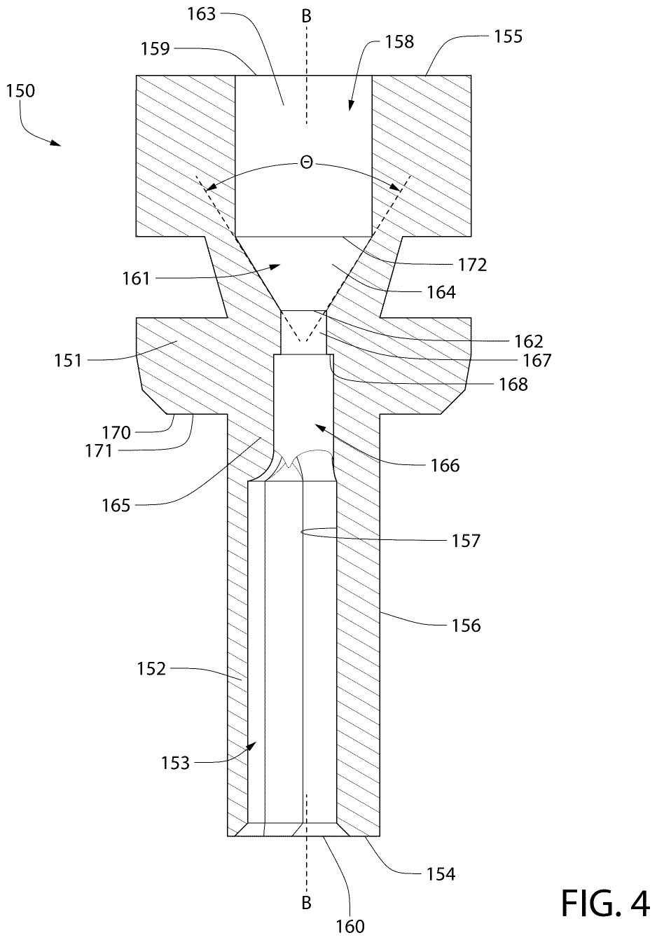

Referring to FIG. 4, the closure member 150 will be described in more detail. The closure member 150 comprises a bottom end 154 and a top end 155. The closure member 150 further comprises an outer surface 156 and an inner surface 157. The inner surface 157 defines or bounds a bore 158 that extends the full length of the closure member 150 from the top end 155 to the bottom end 154. Thus, the closure member 150 comprises a top opening 159 in the top end 154 and a bottom opening 160 in the bottom end 154, with the bore 158 extending continuously through the closure member 150 from the top opening 159 to the bottom opening 160. The closure member 150 comprises a longitudinal axis B-B that extends from the bottom end 154 to the top end 155.

The bore 158 of the closure member 150 comprises a reservoir chamber 161 having an inlet at the top opening 159 and an outlet 162. In the exemplified embodiment, the reservoir chamber 161 comprises a cylindrical section 163 and a funnel section 164. The cylindrical section 163 extends from the top opening 159 that forms the inlet to the funnel section 164. The funnel section 164 extends from an inlet 172 located at the junction between the funnel section 164 and the cylindrical section 163 to the outlet 162. The cylindrical section 163 of the bore 158 has a constant diameter, whereas a diameter of the funnel section 164 continuously decreases with increasing distance away from the cylindrical section 163. In an alternative embodiment, the cylindrical section 163 may be omitted and the funnel section 164 may extend from the opening 159 to the outlet 162. In an embodiment, the diameter of the top opening 159 is the same as the diameter of the cylindrical section 163. In an embodiment, the diameter of the top opening 159 and the cylindrical section 163 is in a range of 3.0 mm to 4.0 mm more specifically 3.2 mm to 3.7 mm, and still more specifically approximately 3.4 mm. This is significantly larger than the diameter of the opening of the NMR tube 100 to which the closure member 150 is configured to be attached, which simplifies the procedure for introducing a liquid sample into the NMR tube 100, as described in more detail below.

The inlet 172 of the funnel section 164 is located closer to the top opening 159 than the outlet 162. In an embodiment, the inlet 172 has a first diameter and the outlet 162 has a second diameter. In an embodiment, a ratio of the first diameter to the second diameter is between 2:1 and 4:1. In one embodiment, the reservoir chamber 161 defines a holding volume between 40 μL and 60 μL, more specifically between 45 μL and 55 μL, and still more specifically approximately 50 μL. In certain embodiments, the holding volume of the reservoir chamber 161 exactly corresponds to the desired volume of the liquid sample to be introduced into the NMR tube 100. In such embodiments, the reservoir chamber 161 is filled completely with the liquid sample, and then the NMR tube assembly 10 is subjected to an external force to pull the liquid sample downwardly from the reservoir chamber 161 into the cavity of the NMR tube 100, as described in more detail herein below.

The funnel section 164 is tapered as it extends from the cylindrical section 163 to the outlet 162. In an embodiment, the funnel section 164 may define a taper angle Θ. In the cross-sectional view of FIG. 4, the taper angle Θ is the angle measured between the inner surface 157 of the funnel section 164 on a first side of the longitudinal axis B-B and the inner surface 157 of the of the funnel section 164 on a second side of the longitudinal axis B-B. In the exemplified embodiment, the taper angle Θ is between 55° and 70°, more specifically between 60° and 65°, and still more specifically approximately 63° (approximately including a tolerance of plus or minus 5%). Stated another way, the inner surface 157 of the funnel section 164 is angled relative to the longitudinal axis B-B at an angle between 25° and 35°, more specifically between 30° and 33°, and still more specifically approximately 31.5°. Thus, as used herein the “taper angle Θ” of the funnel section 164 is twice the angle defined between the sidewall 157 of the funnel section 164 and the longitudinal axis B-B.

The reservoir chamber 158 is configured so that a liquid sample introduced into the reservoir chamber 158 via the top opening 159 in the top end 155 of the closure member 150 does not flow passively through the outlet 162 of the reservoir chamber 158 and into the tube cavity of the NMR tube 100. Rather, the liquid sample that is introduced into the reservoir chamber 158 is maintained and held in the reservoir chamber 158 until an external force acts on the NMR tube assembly 10 to cause the liquid sample to pass through the outlet 162. The liquid sample is configured to be held int eh reservoir chamber 158 due to the taper angle Θ of the funnel section 164 and the resulting surface tension between the inner surface of the funnel section 164 and the liquid sample, the viscosity of the liquid sample, and the small size (diameter) of the outlet 162 (in a range of 0.5 mm to 1.5 mm, in one embodiment between 0.5 mm and 0.7 mm, and in another embodiment between 1.2 mm and 1.4 mm). In an embodiment, the diameter of the outlet 162 may correspond to or match with the diameter of the tube cavity of the NMR tube to which the closure member 150 is attached.

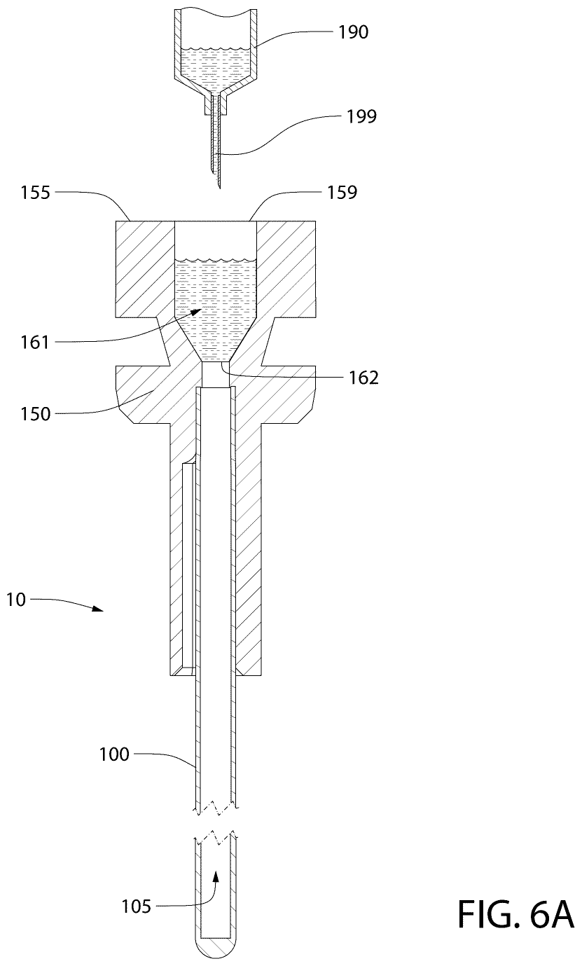

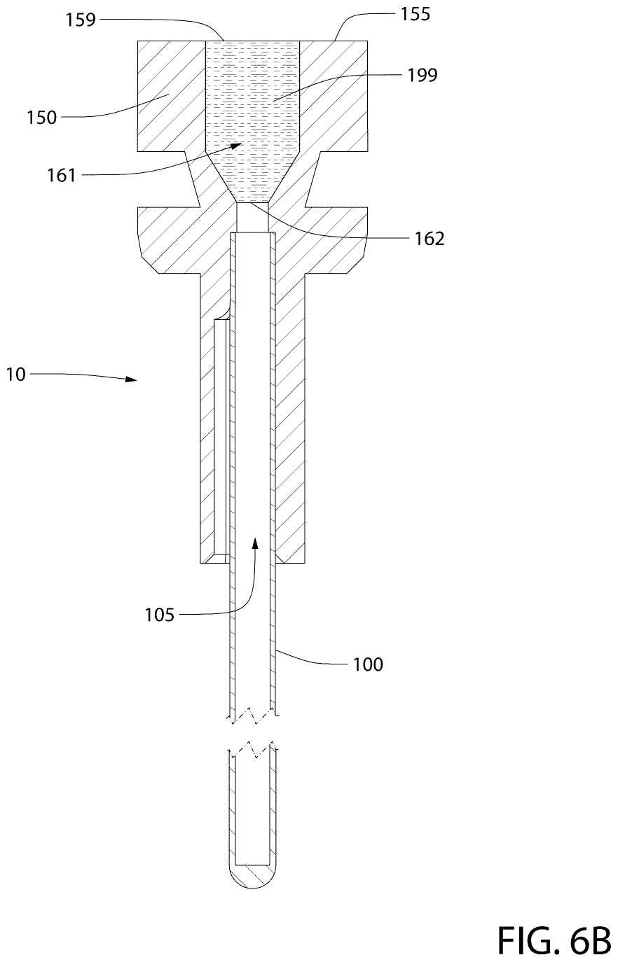

In the exemplified embodiment, the external force that facilitates the transfer of the liquid sample from the reservoir chamber 161 to the tube cavity is a centrifugal force. Thus, as described in more detail below, in the exemplified embodiment the liquid sample that is introduced in the reservoir chamber 158 of the closure member 150 remains in the reservoir chamber 158 of the closure member 150 until the NMR tube assembly 10 is subjected to a centrifugal force, which causes the liquid sample to flow through the outlet 162 and into the tube cavity of the NMR tube 100 to which the closure member 150 is attached. This will be described in greater detail below with reference to FIGS. 6A-9.

As discussed above, the sleeve portion 152 of the closure member 150 defines or comprises the sleeve cavity 153 that extends from the bottom opening 160 in the bottom end 154 towards the funnel section 164. A portion of the sleeve cavity 153 located remote from the bottom end 160 and near to the funnel section 164 forms a tube interface section 166 of the sleeve cavity 153. The tube interface section 166 of the sleeve cavity 153 comprises a plurality of ribs 165 that protrude radially towards the longitudinal axis B-B. The ribs 165 form a sealing interface that is configured to engage with the outer surface of the NMR tube 100 when the closure member 150 is coupled to the NMR tube 100 to achieve the secure friction fit attachment between the closure member 150 and the NMR tube 100. The sealing interface between the closure member 150 and the NMR tube 100 may also serve to prevent leakage during sample loading and analysis.

The bore 158 comprises the reservoir chamber 161 that is configured to receive and hold a liquid sample prior to the liquid sample being transferred into the tube cavity of the NMR tube 100, the tube interface section 166 that is configured to interface with the outer surface of the NMR tube 100 to facilitate the attachment of the closure member 150 to the NMR tube 100, and an intermediate section 167 located between the reservoir chamber 161 and the tube interface section 166. In an embodiment, the intermediate section 167 is located immediately adjacent to the outlet 162 of the reservoir chamber 161 and extends from there to the tube interface section 166. In the exemplified embodiment, the intermediate section 167 has a diameter that matches a diameter of the outlet 162. In the exemplified embodiment, the intermediate section 167 has a constant diameter. The diameter of the outlet 162 and the intermediate section 167 is sufficiently small to prevent the liquid sample introduced into the reservoir chamber 161 from passing into and through the intermediate section 167 without the centrifugal force or some other force as described herein. In an embodiment, the diameter of the intermediate section 167 may be between 0.6 mm and 0.8 mm. In another embodiment, the diameter of the intermediate section 167 may be between 1.2 mm and 1.4 mm. In an embodiment, the diameter of the intermediate section 167 may be the same as the inner diameter of the NMR tube 100 to which the closure member 150 is configured to be attached.

The inner surface 157 of the closure member 150 defines a first shoulder 168 at the intersection between the intermediate section 167 and the tube interface section 166. In the exemplified embodiment, the first shoulder 168 faces downwardly towards the bottom end 154 of the closure member 150. The first shoulder 168 is located within the bore 158 of the closure member 150. In the exemplified embodiment, the first shoulder 168 has a length measured from the inner surface 157 of the sleeve interface section 166 to the inner surface 157 of the intermediate section 167. The length of the first shoulder 168 may be between 0.2 and 0.6 mm, for example. In the exemplified embodiment, when the closure member 150 is attached to the NMR tube 100 the top edge or end of the NMR tube 100 is adjacent to and/or in contact with the first shoulder 168.

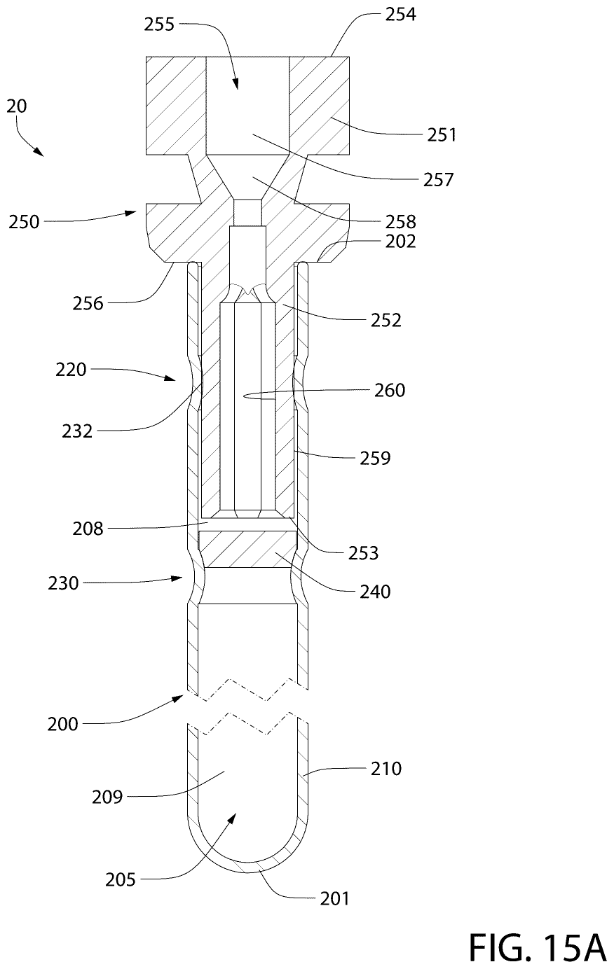

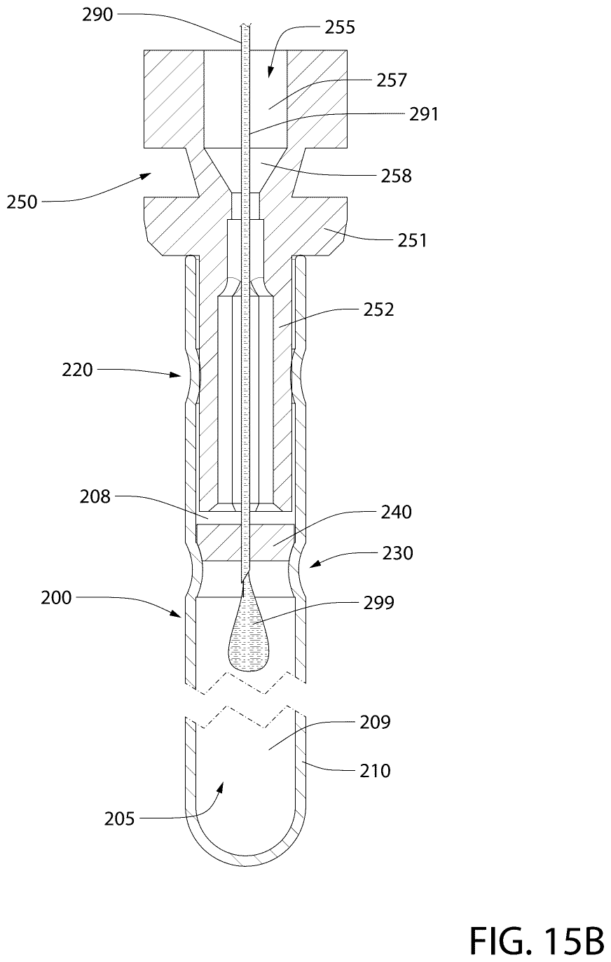

The head portion 151 of the closure member 150 comprises a bottom end 170 and a top end that forms the top end 155 of the closure member 150. The bottom end 170 of the head portion 151 protrudes radially outward from the outer surface 156 of the sleeve portion 152 and forms a second shoulder 171. The second shoulder 171 faces downwardly towards the bottom end 154 of the closure member 150. In an alternative embodiment, the closure member 150 may be coupled to an NMR tube with the sleeve portion 152 of the closure member 150 located inside of the cavity of the NMR tube such that the top end of the NMR tube abuts against the second shoulder 171 of the head portion 151 of the closure member 150 (see, for example, FIG. 15A, discussed in more detail below).

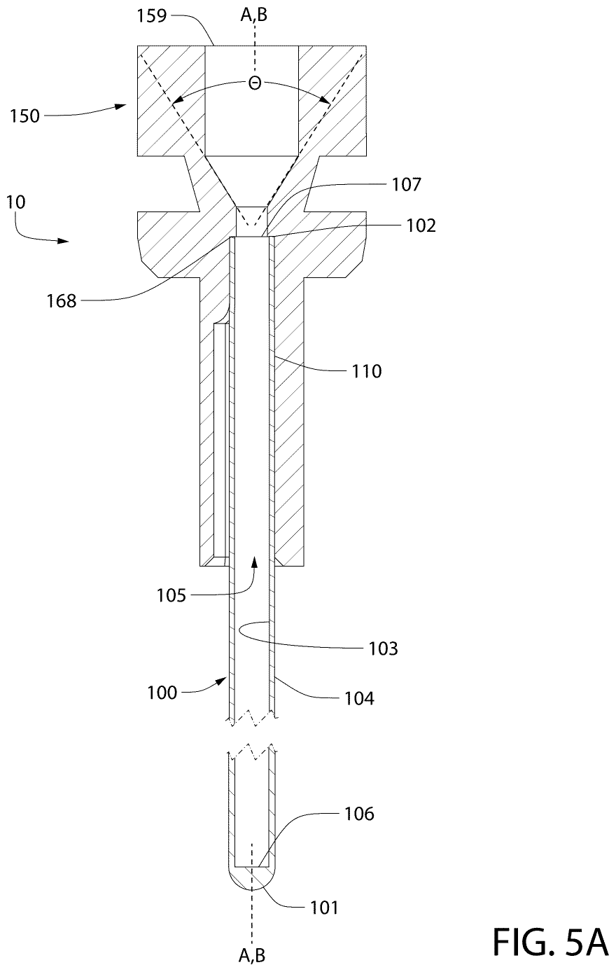

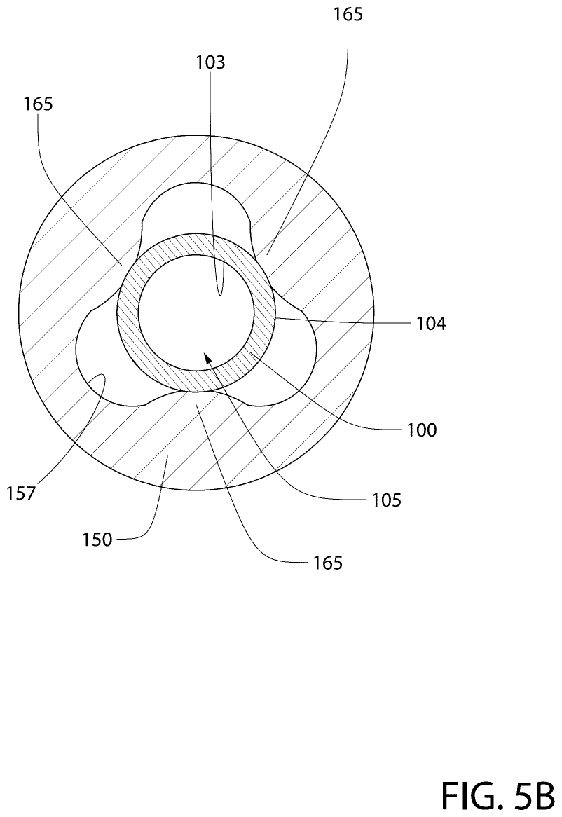

Referring to FIG. 5A, the NMR tube assembly 10 with the closure member 150 attached to the NMR tube 100 is illustrated in cross-section. The NMR tube 100 has an inner surface 103 and an outer surface 104 opposite the inner surface 103. The inner surface 103 of the NMR tube 100 defines a tube cavity 105 that extends from a floor 106 to an opening 107 in the top end 102 of the NMR tube 100. The tube cavity 105 is configured to receive and hold a liquid sample. As mentioned previously, in the exemplified embodiment when the closure member 150 is coupled to the NMR tube 100, the top end 102 of the NMR tube 100 abuts against the first shoulder 168 of the closure member 150. In an embodiment, the volume of the reservoir chamber 161 of the closure member 150 is an exact match to the desired fill volume for the NMR tube 100. When the closure member 150 is coupled to the NMR tube 100, a top portion 110 of the NMR tube 100 is located within the sleeve cavity 153 of the closure member 150.

As shown in FIG. 5B, the ribs 165 of the tube interface section 166 of the closure member 150 are in surface contact with the outer surface 104 of the top portion 110 of the NMR tube 100. In the exemplified embodiment, there are three of the ribs 165 located in a circumferentially spaced apart manner. The engagement of the ribs 165 with the outer surface 104 of the top portion 110 of the NMR tube 100 creates a press fit or friction fit or interference fit between the closure member 150 and the NMR tube 100. In an alternative embodiment, the ribs 165 (which are somewhat elongated in the axial direction) may be replaced with protrusions or protuberances having a smaller footprint (dome shaped protrusions, for example).

In an embodiment, the top opening 159 of the closure member 150 has a first diameter and the tube cavity 105 of the NMR tube 100 has a second diameter. In an embodiment, the first diameter is at least 2.5 times greater than the second diameter. In an embodiment, the first diameter is at least 3 times greater than the second diameter. In another embodiment, the first diameter is between 3 and 3.5 times greater than the second diameter. Due to the larger diameter of the top opening 159 of the closure member 150 as compared to the diameter of the opening 107 of the NMR tube 100, it is easier for a user to introduce a liquid sample into the tube cavity 105 via the top opening 159 in the cover member 150 then it would be to introduce a liquid sample directly into the tube cavity 105 through the opening 107 of the tube cavity 105 (as is done using traditional filling methods). Specifically, it requires very precise positioning of the syringe or pipette through the very small opening 107 for direct introduction of the liquid sample into the tube cavity 105, whereas if the closure member 150 is coupled to the NMR tube 100 and the liquid sample is introduced into the tube cavity 105 via the top opening 159 in the closure member 150, less precision is required due to the larger size of the top opening 159 as compared to the opening 107.

In traditional processes, a long needle attached to a syringe or pipette is inserted to the bottom of the NMR tube, and then the liquid sample is slowly dispensed into the NMR tube while withdrawing the needle. Visual monitoring is required to achieve the correct fill level, and extreme care is required to avoid forming bubbles within the liquid sample in the tube cavity. Air bubbles are a primary challenge when filling small diameter (e.g., 1.7 mm or 1.0 mm) NMR tubes. A 1.7 mm tube has an inner diameter of approximately 1.2 mm and an outer diameter of approximately 1.7 mm, with a length of 7-10 cm. A 1.0 mm tube has an inner diameter of approximately 0.6 to 0.7 mm, an outer diameter of 1.0 mm, and a length of 7-10 cm. The narrow bores of these two small tube sizes creates very high surface tension for the liquid, which requires the filling process to be very precise. The term approximately as used with regard to the inner diameter of the NMR tubes includes a tolerance of plus or minus 0.1 mm

Specifically, in the narrow bores of the small diameter NMR tubes, surface tension dominates over gravity. The liquid sample introduced into the cavity of the small diameter NMR tubes “sticks” to the tube walls. When dispensing, the liquid tends to bead up rather than flow smoothly and contact between the needle and liquid creates meniscus effects. Furthermore, withdrawing the needle often pulls liquid upward, creating gaps. These gaps immediately trap air bubbles.

There are several ways that air bubbles are formed using conventional NMR tube filling processes. During initial dispensing: if liquid is dispensed too quickly, turbulence creates bubbles. During needle withdrawal: the needle breaking contact with liquid surface creates bubbles. From tube wall adhesion: liquid sticking to walls creates gaps that fill with air. From viscosity effects: viscous samples flow slowly, allowing air to become trapped behind the liquid front. From pressure differences: Negative pressure created as needle withdraws can pull air into the liquid.

Bubble formation can be catastrophic for nuclear magnetic resonance (NMR). Bubbles create magnetic susceptibility mismatches, cause baseline distortions in spectra, produce spinning sidebands, and make shimming (magnetic field homogenization) difficult or impossible. A single bubble can ruin an entire NMR measurement. Samples with bubbles often need to be discarded and reloaded.

Traditional bubble avoidance techniques include some of the following. Dispensing extremely slowly (often taking 3-5 minutes per tube). Keeping the needle tip always submerged in the liquid during dispensing. Withdrawing the needle at exactly the same rate as dispensing. Using steady hands with no tremor. All of this requires extensive operator training and experience. In fact, even experienced operators fail 20-40% of the time. Some operators use vacuum degassing before loading, which adds time and complexity. For a skilled operator, the traditional NMR tube filling process takes 2-5 minutes per tube for bubble-free loading. For a less skilled operator, the traditional NMR filling process can take 5-10 minutes per tube, with higher failure rate. For 96 samples, this equates to 3.2 to 16 hours of labor, which is completely impractical for high-throughput applications.

Robotic liquid handlers struggle even more with bubble formation. Robots lack the tactile feedback of human operators. Programming to avoid bubbles requires extremely slow dispensing. Positioning accuracy must be sub-millimeter. Any vibration or movement creates bubbles. Long needles required for 1 mm/1.7 mm tubes are fragile and expensive. Needle damage from tube contact is common.

The method described below addresses the fundamental challenges with the conventional/standard method for filling small diameter (e.g., 1 mm and 1.7 mm) NMR tubes. Instead of dispensing the liquid sample directly into the narrow tubes (where bubbles form), in accordance with the inventive method described herein the liquid sample is dispensed into large reservoir chambers 161 located inside of the closure member 150 that is attached to the NMR tube 100 (where bubbles don't form). Then, the NMR tube assembly 10 (which comprises the NMR tube 100 with the attached closure member 150 with the reservoir chamber 161 filled with the sample liquid), is subjected to a centrifugal force to transfer the liquid sample from the reservoir chamber 161 of the closure member 150 into the tube cavity 105 of the NMR tube 100. This process avoids the generation of bubbles, and if bubbles happen to form, they are eliminated in the centrifugation process. The method described herein separates the dispensing step from the tube filling step, solving both the bubble problem and the throughput problem simultaneously.

Referring to FIGS. 6A and 6B, a method for loading liquid samples into the reservoir chamber 161 of the closure member 150 of the NMR tube assembly 10 will be described. The first step is to attach the closure member 150 to the top portion of the NMR tube 100 as previously described. Because the closure member 150 comprises the bore 158 that extends through the full length of the closure member 150, the top opening 159 in the top end 155 of the closure member 150 is in fluid communication with the tube cavity 105 of the NMR tube 100. As such, a liquid introduced into the reservoir chamber 161 of the closure member 150 via the top opening 159 is able to flow into the tube cavity 105, albeit not passively by gravity alone, as described further herein.

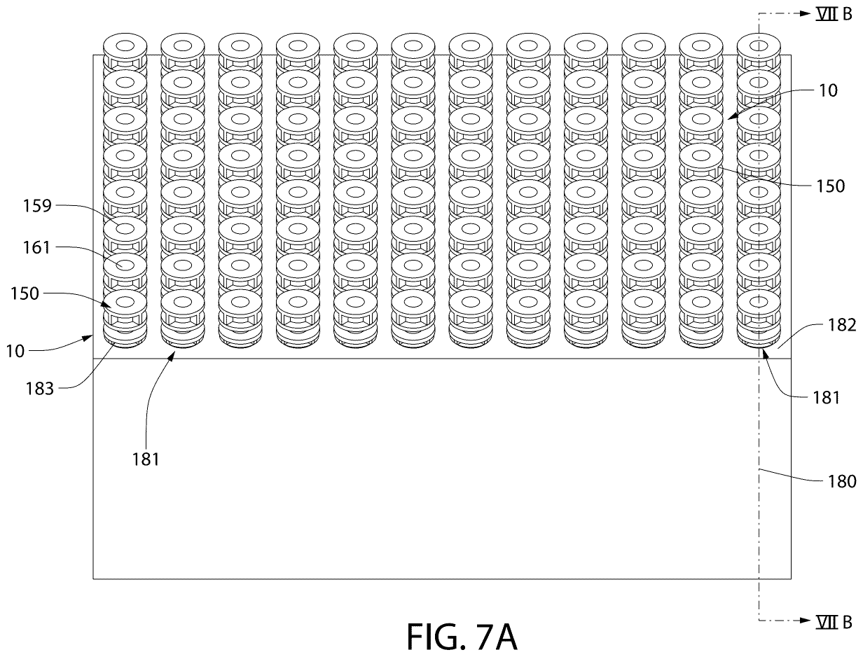

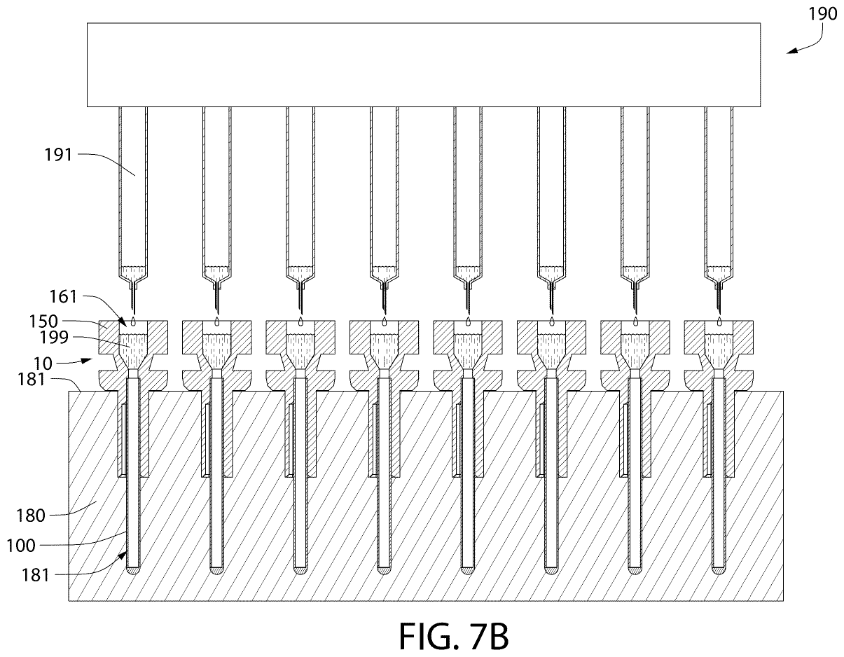

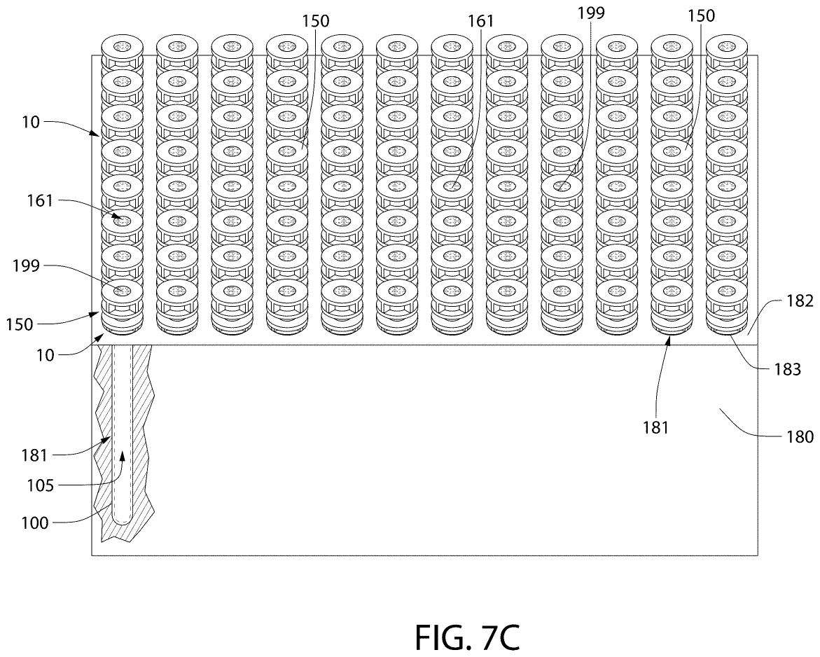

Once the closure member 150 is coupled to the NMR tube 100, a liquid sample 199 can be introduced into the reservoir chamber 151 of the closure member 150 via the top opening 159 of the closure member 150. In the exemplified embodiment, the liquid sample 199 is introduced into the reservoir chamber 151 from a liquid dispensing device 190. The liquid dispensing device 190 may comprise a syringe or a pipette. Alternatively, the liquid dispensing device 190 may comprise an automated liquid handler, which uses a motorized pipette or syringe attached to a robotic arm to dispense a specified volume of liquid to a designated area. As described below, such an automated liquid handler may comprise a plurality of dispensing devices (i.e., syringes, pipettes, or the like) for dispensing the liquid sample into a plurality of the closure members 150 simultaneously. Thus, when the liquid dispensing device 190 is an automated liquid handler, the automated liquid handler may be an 8-channel, or 12-channel, or 16-channel, or 96-channel, or any other desired size liquid handler (the number of channels is the number of dispensing devices (e.g., syringes and pipettes) associated with the liquid handler). The concept of filling multiple of the reservoir chambers 161 with a multi-channel liquid handler will be described further with reference to FIG. 7A-7C.

With continued reference to FIGS. 6A and 6B, as the liquid dispensing device 190 dispenses the liquid sample 199 into the reservoir chamber 161 of the closure member 150, the liquid sample 199 fills the reservoir chamber 161 without flowing through the outlet 162 of the reservoir chamber 161 and into the cavity 105 of the NMR tube 100. Rather, the liquid sample 199 remains housed in the reservoir chamber 161 until some later action is taken, such as subjecting the NMR tube assembly 10 to a centrifugal force, as described below. In the exemplified embodiment, the liquid sample 199 is dispensed into the reservoir chamber 161 until the liquid sample 199 fills the reservoir chamber 161 entirely from the outlet 161 to the top opening 159. This is preferable in some embodiments because the volume of the reservoir chamber 161 is matched to the desired fill volume of the NMR tube for spectroscopy. Specifically, the volume of the reservoir chamber 161 is such that when filled to capacity and permitted to flow into the tube cavity 105 of the NMR tube 100, the height of the liquid sample 199 in the tube cavity 105 spans the active region of the NMR coil while providing adequate volume for proper shimming. In some embodiments, this may be between 40 μL and 80 μL, or more specifically between 40 μL and 60 μL, although the exact volume may be determined based on specific user needs.

While prior filling methods required the syringe or pipette needle to be inserted to the bottom of the tube cavity 105 as described above, with the inventive method the syringe or pipette does not need to be inserted into the tube cavity 105 at all. In fact, in some embodiments, the liquid sample 199 can be dispensed into the reservoir chamber 161 without any part of the liquid dispensing device 190 being inserted through the top opening 159 in the closure member 150. Thus, the liquid sample 199 can be introduced into the reservoir chamber 161 by dispensing the liquid sample 199 through the top opening 159 without inserting any part of the liquid dispensing device 190 through the top opening 159. In an alternative embodiment, a portion of the liquid dispensing device 190 can be inserted into the top opening 159 during dispensing operations to ensure that the liquid sample 199 is properly dispensed into the reservoir chamber 161. The liquid dispensing device 190 should not be inserted beyond the outlet 162 of the reservoir chamber 161 to ensure that the liquid sample 199 is dispensed into the reservoir chamber 161 rather than directly into the tube cavity 105. As noted, the liquid sample 199 is held and maintained in the reservoir chamber 161 until some positive action or force is applied onto the NMR tube assembly 10.

Referring now to FIG. 7A, a plurality of the NMR tube assemblies 10 are illustrated supported in a tube rack 180. The tube rack 180 comprises a plurality of wells (or receptacles or slots) 181, each of the wells 181 being configured to hold one of the NMR tube assemblies 10. The tube rack 180 has a top end 182, and each of the plurality of wells 181 has an opening 183 in the top end 182 of the tube rack 180. Each of the NMR tube assemblies 10 is inserted into one of the wells 181 of the tube rack 180 through the opening 183 in the top end 182 of the tube rack 180. The NMR tube assemblies 10 comprise the NMR tubes 100 (not visible since they are located inside of the tube rack 180) and the closure members 150 coupled to the NMR tubes 100. While the NMR tubes 100 are located inside of the wells 181, the closure members 150 protrude from the opening 183 in the top end 182 of the tube rack 180 and are accessible for liquid loading into the reservoir chambers 161 thereof. Thus, in this embodiment, the NMR tube assemblies 10 are formed by attaching the closure members 150 to the NMR tubes 100 and then the NMR tube assemblies 10 are positioned in the wells 181 of the tube rack 180 before any liquid sample is introduced into the closure members 150 or the NMR tubes 100. The NMR tube assemblies 10 are empty (i.e., free of liquid therein) in the illustration shown in FIG. 7A.

The tube rack 180 is not limited to any particular design, shape, or style, but can be any rack with wells for holding and supporting tubes as described herein and well known in the art. In some embodiments, the tube rack 180 may have various openings in its sidewalls to render the NMR tubes 100 visible. The tube rack 180 may be formed from a rigid plastic, such as for example without limitation polypropylene or polycarbonate. The tube rack 180 may comprise the wells 181, which may form individual tube receptacles. The NMR tube assemblies 10 are configured to be held vertically within the wells 181 with closure members 150 exposed at the top end 182 of the tube rack 180. In an embodiment, the tube rack 180 has sufficient structural strength to withstand centrifugation. The tube rack 180 may be disposable or reusable.

In the exemplified embodiment, the tube rack 180 has 96 of the wells 181 arranged in an 8×12 matrix. However, other size tube racks may be used in alternative embodiments (24-well, 48-well, 384-well-etc). Furthermore, in some embodiments the tube rack 180 may be adapted for different tube densities and different tube spacings. However, in any case the tube rack 180 defines wells for holding a plurality of the NMR tube assemblies 10 in a defined array of tubes with closure members thereon. The tube rack 180 may have a standard microplate footprint (127.76 mm×85.48 mm) so that the tube spacing matches standard microplate spacing. In an embodiment, the tube rack 180 is compatible with standard liquid handling equipment. In an embodiment, the tube rack 180 is compatible with standard microplate centrifuges.

Referring to FIG. 7B, a method of filling the NMR tube assemblies 10 that are located in the tube rack 180 will be described. In this embodiment, the liquid dispensing device 190 is an automatic liquid handler, and more specifically an 8-channel liquid handler. Examples of liquid handlers that could be used include Eppendorf Multipette, Integra VIAFLO, Rainin Pipet-Lite Multi, Hamilton Microlab Star, Tecan Freedom EVO, etc. (any multi-channel liquid handler can be used for this purpose).

The liquid dispensing device 190 comprises eight dispensers 191, each of which is configured to introduce the liquid sample into the reservoir chamber 161 of one of the closure members 150 of one of the NMR tube assemblies 10. In the exemplified embodiment, the tube rack 180 has eight rows (or, stated another way, there are eight of the NMR tube assemblies 10 in each column). Therefore, the liquid dispensing device 190 is configured to hover above the NMR tube assemblies 10 in the tube rack 180 column-by-column to introduce the liquid sample into each of the reservoir chambers 161, eight at a time. Specifically, the liquid dispensing device 190 is first positioned above the first column of the NMR tube assemblies 10 whereby each of the dispensers 191 is aligned with the reservoir chamber 161 of one of the NMR tube assemblies 10, and then the liquid dispensing device 190 is activated to fill the reservoir chambers 161 of the NMR tube assemblies 10 in the first column with the liquid sample 199. Then, the liquid dispensing device 190 or the tube rack 180 is moved so that the liquid dispensing device 190 is positioned above and aligned with the second column of the NMR tube assemblies 10 and then activated to fill the reservoir chambers 161 of the NMR tube assemblies 10 in the second column with the liquid sample 199. This continues until all 96 of the NMR tube assemblies 10 are filled to the desired amount (i.e., the reservoir chambers 161 thereof are filled to capacity). As mentioned, the number of the NMR tube assemblies 10 in the tube rack 180 may be modified from that which is shown in the exemplified embodiment. In the exemplified embodiment, no portion of the liquid dispensing device 190 is located within the reservoir chamber 161 or within any other part of the NMR tube assembly 10 during the dispensing. In other embodiments, a tip end of the liquid dispensing device 190 may be partially located within the reservoir chamber 161 during the dispensing of the liquid sample 199 therein.

In one embodiment, the reservoir chamber 161 of all 96 of the NMR tube assemblies 10 can be filled with the liquid sample 199 in a time period of 3-5 minutes. Because the top opening 159 of the closure member 150 is larger than the typical opening of the NMR tube 100, less precision is required during the filling operation. Furthermore, there is lower surface tension which allows the liquid sample 199 to be dispensed at a normal speed. Moreover, the needle does not need to be inserted into a narrow bore, and the needle does not need to be withdrawn during the dispensing. Rather, the liquid sample 199 simply flows into the reservoir chamber 161 as it is dispensed from the liquid dispensing device 190. Thus, using the methods described herein, as compared to conventional filling processes, the filling process has a relaxed positioning tolerance, eliminates most positioning errors, reduces needle damage from tube wall contact, and allows the use of less expensive liquid handlers. The reservoir chambers 161 can simply be filled to capacity, and there is no need to visually monitor the fill level. Rather, the reservoir chambers 161 are filled until full, which can be readily determined by the robot or the operator, or predetermined since the volume of the reservoir chamber 161 is known.

Referring to FIG. 7C, the plurality of NMR tube assemblies 10 are illustrated in the tube rack 180, with the reservoir chamber 161 of the closure member 150 of each of the NMR tube assemblies 10 filled with the liquid sample 199. A portion of the tube rack 180 is illustrated broken away to show that at this point in the filling process, the NMR tubes 100 remain empty. That is, none of the liquid sample 199 has passed into the tube cavity 105 of the NMR tubes 105. Rather, the liquid sample 199 remains held and maintained in the reservoir chamber 161 until further processing actions are taken, as described below. Thus, the liquid sample 199 is dispensed into the reservoir chamber 161 of the closure member 150 and remains in the reservoir chamber 161 of the closure member 150 without flowing passively into the tube cavity 105. Further action is required to transfer the liquid sample 199 from the reservoir chamber 161 to the tube cavity 105 of the NMR tube 100 to which the closure member 150 is attached.

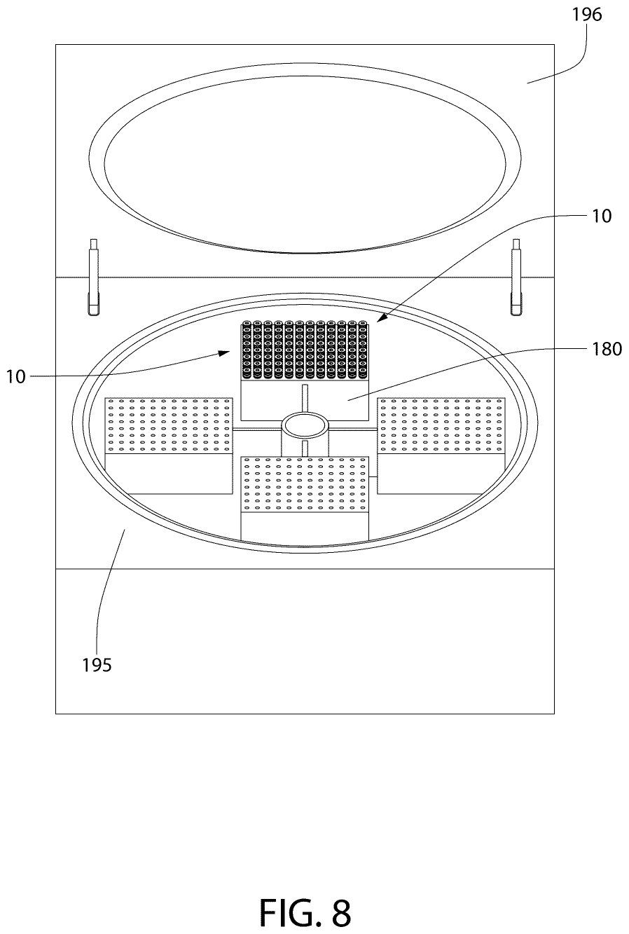

Referring to FIG. 8, the method for loading the liquid samples into the NMR tubes 100 is further described. The tube rack 180 containing the NMR tube assemblies 10 with the reservoir chambers 161 of the closure members 150 filled with a desired volume of the liquid sample 199 is placed into a rotor of a centrifuge 195. In the exemplified embodiment, the centrifuge 195 is configured to hold up to four of the tube racks 180. In alternative embodiments, the centrifuge 195 may be configured to hold just one of the tube racks 180 or any other number of the tube racks 180 as desired. In still another embodiment, the centrifuge 195 may be configured to hold one or more of the NMR tube assemblies 10 without the NMR tube assemblies 10 being in a tube rack. That is, one or more of the NMR tube assemblies 10 may be subjected to the centrifugal force within the centrifuge 195 independently, without being located in a tube rack 180. In an embodiment, the centrifuge 195 may be configured to hold one or more tube racks 180 holding a plurality of the NMR tube assemblies 10 and also separately to hold one or more of the NMR tube assemblies 10 that are not located in the tube rack 180.

After the tube rack 180 containing the NMR tube assemblies 10 and/or the independent NMR tube assemblies 10 are located in the centrifuge 195, the lid 196 of the centrifuge 195 is closed and the centrifuge 195 is activated. In an embodiment, the centrifuge 195 may be configured to operate at a speed of 1000-3000 RCF (relative centrifugal force), or more specifically 1500-2500 RCF. In an embodiment, the centrifuge 195 is configured to operate for a duration between 1-5 minutes, or more specifically between 2-4 minutes. In an embodiment, the centrifuge 195 is configured to operate at room temperature such that no heating or cooling is required. After the set operation time period has expired, the centrifuge 195 may be deactivated and permitted to stop.

During the centrifugation, the NMR tube assemblies 10 are subjected to a centrifugal force which drives the liquid sample 199 downwardly within the NMR tube assemblies 10 and into the tube cavities 105 of the NMR tubes 100. Specifically, the liquid sample 199 is forced out of the reservoir chamber 161 and flows through the tapered funnel and out through the outlet 162. The tapered walls of the funnel section 164 with the taper angle Θ as described prevents the liquid sample 199 from adhering to the walls of the funnel section 164 and permits the liquid sample 199 to flow downwardly into the tube cavity 105. The bore 158 of the closure member 150 does not have any corners or flat surfaces to trap the liquid sample 199, which permits the liquid sample 199 to flow efficiently into the tube cavity 105 below.

Moreover, during the centrifugation, any bubbles that may have been present in the liquid sample 199 are subjected to the same centrifugal force. The bubbles are less dense than the liquid, and the centrifugal force drives the bubbles towards the center of rotation (upward relative to the liquid). Thus, the bubbles are forced to the surface of the liquid or out of the liquid entirely. Even microbubbles are compressed to negligible size by pressure. The result is a bubble-free liquid sample in the tube cavity 105 of the NMR tubes 100. In one embodiment, the above occurs completely automatically. There is no operator skill required and no special techniques needed. The physics of centrifugation may ensure that the bubbles are completely removed from the liquid sample 199.

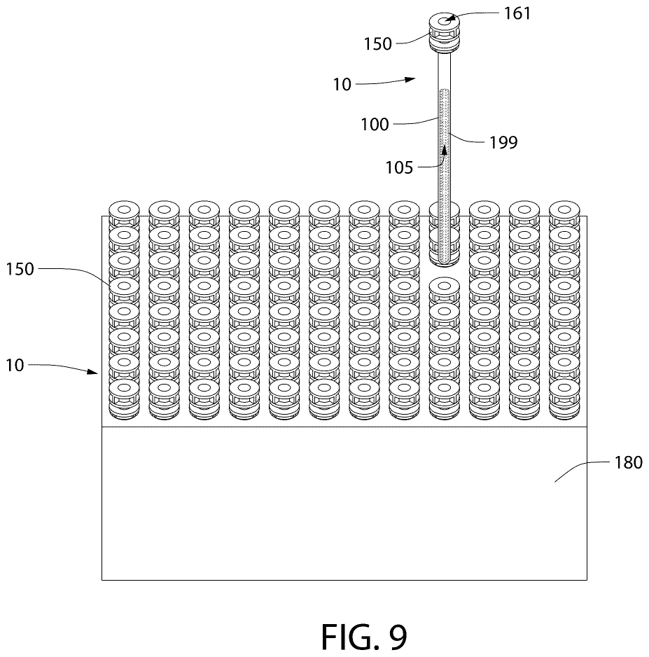

Next, as shown in FIG. 9, the tube rack 180 containing the NMR tube assemblies 10 is removed from the centrifuge 195. The tube rack 180 is illustrated with the NMR tube assemblies 10 supported, and the liquid sample 199 is no longer visible in the reservoir chamber 161 of the closure member 150. This is because the liquid sample 199 has been transferred into the tube cavity 105 of the NMR tube 100. One of the NMR tube assemblies 10 is shown removed from the tube rack 180 so that the liquid sample 199 located within the tube cavity 105 is visible. The centrifugal force has caused all of the liquid sample 199 to move from the reservoir chamber 161 of the closure member 150 to the tube cavity 105 of the NMR tube 100.

In an embodiment, the filling process may be 20-50 times faster than the traditional filling methods (for filling 96 tubes as set forth in the exemplified embodiment described above). Thus, 96 NMR tubes can be filled with liquid samples in less than ten minutes, as compared to 3-16 hours using traditional methods. Furthermore, using the centrifugal force provides a physics-based solution to the problem of bubbles in the liquid sample, and it is highly effective. The above methods are primarily focused on 1 mm and 1.7 mm tubes and makes these small diameter tubes practical for high-throughput, whereas previously this was nearly impossible. The methods described herein may be useful for other tube sizes, including larger NMR tubes.

The NMR tubes 100 now contain bubble-free samples at the bottom of the tube cavities 105. The closure members 150 remain in place and may serve as sealed caps. Next, the user may keep the closure members 150 in place on the NMR tubes 100 and proceed to analysis. Alternatively, the user may remove the closure members 150 from the NMR tubes 100 and install different closures or caps, if needed. In another embodiment, the tube rack 180 may be transferred to an NMR sample changer for automated analysis.

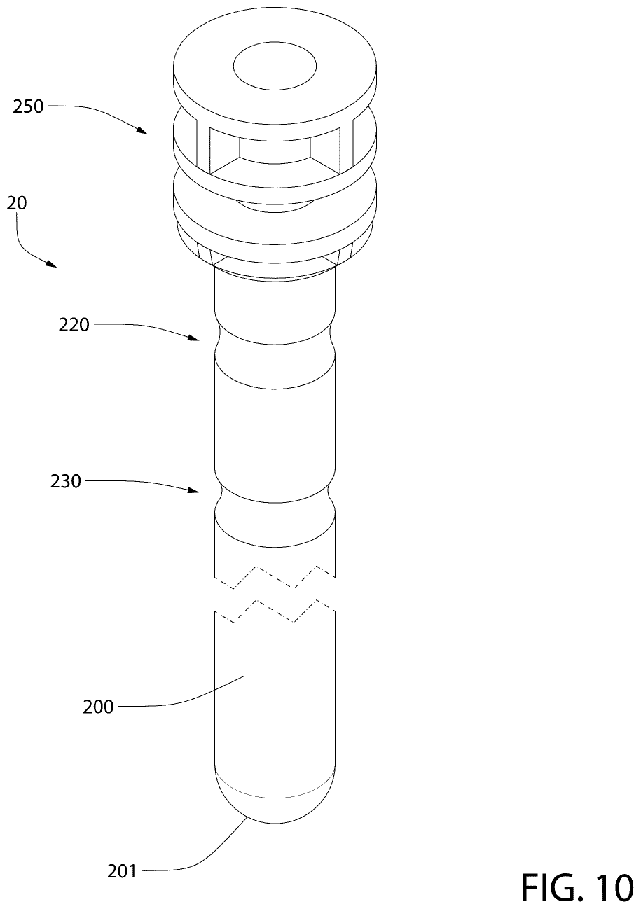

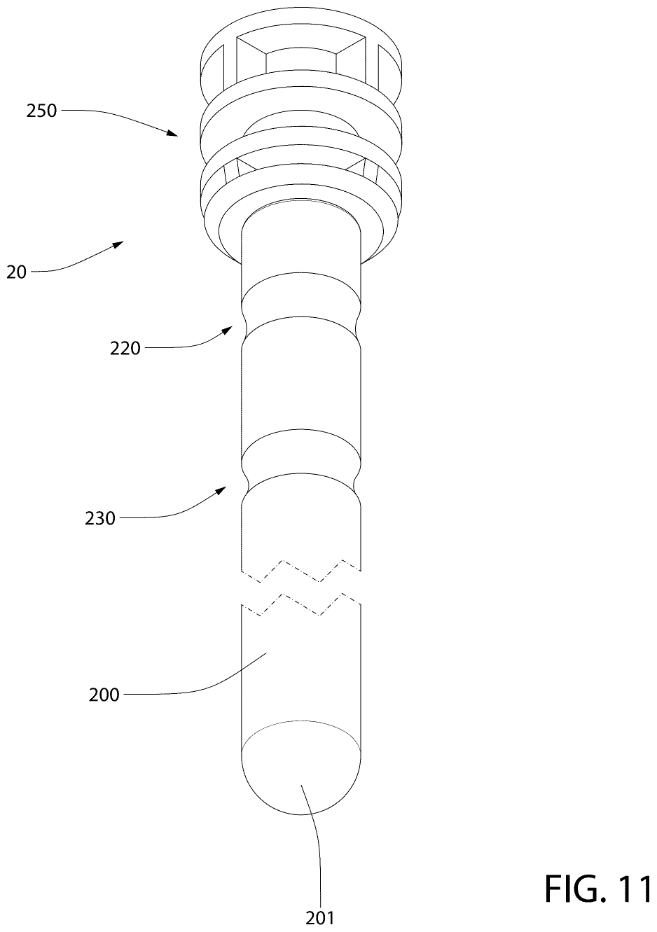

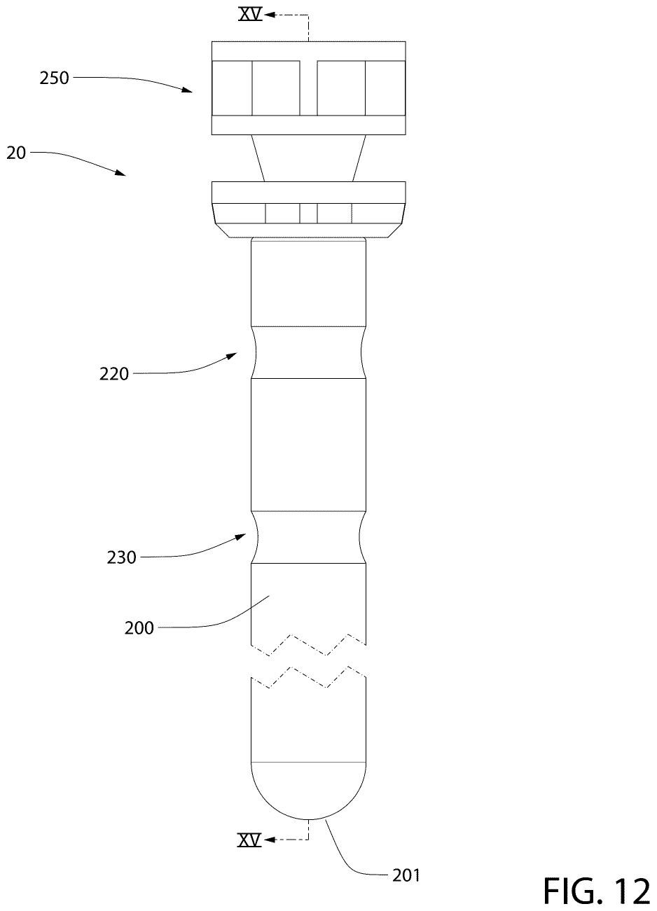

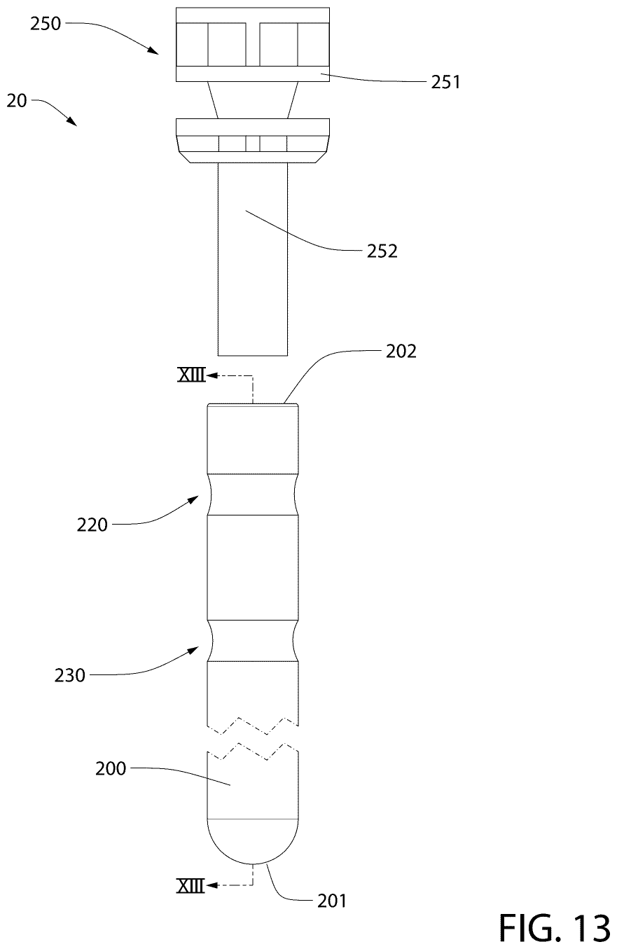

Referring to FIGS. 10-13, an NMR tube assembly 20 is illustrated in accordance with another embodiment of the present invention. The NMR tube assembly 20 generally comprises an NMR tube apparatus 200 and a closure member 250. The NMR tube apparatus 200 comprises an NMR tube 210.

In one embodiment, the closure member 250 is identical to the closure member 150 described above with reference to the NMR tube assembly 10. Thus, in some embodiments the description of the closure member 150 provided above is applicable to the closure member 250 in its entirety. The closure member 250 comprises a head portion 251 and a sleeve portion 252. However, in this embodiment of the NMR tube assembly 20, the closure member 250 is coupled to the NMR tube 210 by inserting the sleeve portion 252 of the closure member 250 into the interior of the NMR tube 210. Thus, whereas with the NMR tube assembly 10 the NMR tube 100 was inserted into the interior of the sleeve portion 152 of the closure member 250, in this embodiment the opposite occurs. However, as mentioned, the closure member 250 may be identical to the closure member 150.

Thus, in one embodiment the invention may be directed to an NMR tube system that comprises a first NMR tube 100, a second NMR tube 210, and a closure member 150, 250. The closure member 150, 250 may be configured to be coupled to the first NMR tube 100 by inserting a top portion of the first NMR tube into the sleeve cavity of the sleeve portion 152, 252 of the closure member 150, 250. The closure member 150, 250 may further be configured to be coupled to the second NMR tube 100 by inserting the sleeve portion 152, 252, of the closure member 150, 250 into a top portion of the tube cavity of the second NMR tube 210. Thus, the same closure member 150, 250 may be configured to be used to close the open top end of two distinct NMR tubes 100, 210 with different inner diameters. The same exact closure member 150, 250 with the same exact dimensions may be configured to be attached to two different NMR tubes 100, 210 with two different inner and outer diameters.

Returning to the specific embodiment of the NMR tube assembly 20, the NMR tube apparatus 200 comprises a bottom end 201 and a top end 202. The NMR tube apparatus 200 is elongated along an axis between the bottom and top ends 201, 202. The NMR tube 210 of the NMR tube apparatus 200 further comprises at least one constriction. In the exemplified embodiment, the NMR tube 210 of the NMR tube apparatus 200 comprises a first constriction 220 and a second constriction 230 that are axially spaced apart from one another. In the exemplified embodiment, the first constriction 220 is located closer to the top end 202 than the second constriction 230. The NMR tube 210 may be formed from glass, such as borosilicate (as with all of the NMR tubes described herein).

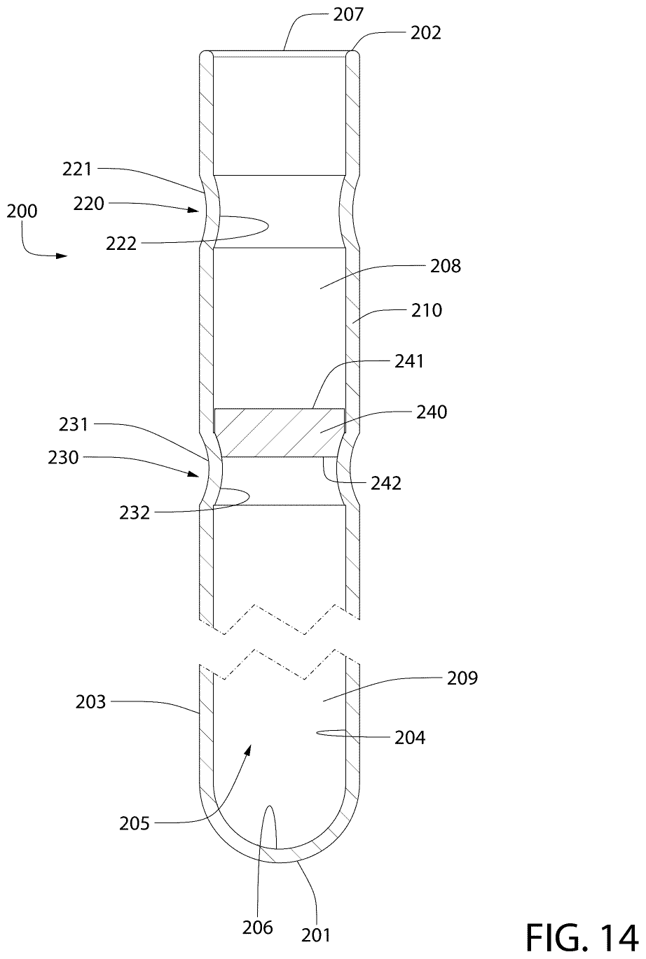

Referring to FIG. 14, the NMR tube apparatus 200 comprises the NMR tube 210 and a septa 240. The NMR tube 210 comprises an outer surface 203 and an inner surface 204. The inner surface 204 of the NMR tube 210 defines a tube cavity 205 having a floor 206 and an opening 207 at the top end 202. As noted above, the NMR tube 210 comprises the first constriction 220 and the second constriction 230. In the exemplified embodiment, each of the first and second constrictions 220, 230 comprises an annular dimple 221, 231 formed on the outer surface 203 of the NMR tube 210 and an annular protuberance 222, 232 formed on the inner surface 204 of the NMR tube 210. Thus, the first and second constrictions 220, 230 form a concave ring-shaped region on the outer surface 203 and a convex ring-shaped region on the inner surface 204. The annular protuberance 222, 232 protrudes inwardly relative to the rest of the inner surface 204 towards a longitudinal axis of the NMR tube 210.

While the first and second constrictions 220, 230 are described above as being annular and forming annular concave and convex regions on the opposing outer and inner surfaces 203, 204 of the NMR tube 210, the invention is not to be so limited in all embodiments. In other embodiments, the first and second constrictions 22, 230 may comprise a plurality (two or more) of spaced apart dimples on the outer surface 203 (and corresponding protuberances on the inner surface 204), with the dimples and protuberances being arranged in a ring-like shape or being arranged on opposite sides of a longitudinal plane in which the longitudinal axis of the NMR tube 200 lies. That is, the first and second constrictions 220, 230 could be formed by discontinuous dimples/protuberances rather than singular continuous ring-shaped dimples/protuberances.

In the exemplified embodiment, the septa 240 is a generally disk-shaped shaped member that is positioned within the tube cavity 205 of the NMR tube 210. The septa 240 is positioned in the tube cavity 205 in engagement with the second constriction 230 to secure the septa 240 within the tube cavity 205 of the NMR tube 210. In an embodiment, the septa 240 is in engagement with a top portion of the second constriction 230, with the remainder of the second constriction 230 located between the septa 240 and the floor 206 of the tube cavity 205. In an embodiment, the septa 240 comprises an annular engagement feature 243 that is configured to mate with the annular protrusion 232 of the second constriction 230. In an embodiment, the annular engagement feature 243 is a recess or concave region that is configured to receive and mate with the convex shape of the annular protrusion 232 of the second constriction 230 to maintain the septa 240 in place within the tube cavity 205.

The second constriction 230 serves as an exact positioning element for the septa 240 and prevents over-insertion of the septa 240. In an embodiment, once the septa 240 is inserted into the tube cavity 205, the septa 240 is permanently positioned between the secondary constriction 230 and the closure member 250 (when the closure member 250 is attached to the NMR tube 210). Thus, in the exemplified embodiment the septa 240 is not removed from the tube cavity 205 once placed therein. The second constriction 230 also creates a precise reference point for automated needle penetration, discussed further below. The septa 210 in position divides the tube cavity 205 into a top portion 208 located between the septa 240 and the top end 202 of the NMR tube 210 and a bottom portion 209 located between the septa 240 and the bottom end 206 of the NMR tube 210.

In an embodiment, the septa 240 is formed from an elastomeric material, such as for example without limitation silicone. The septa 240 comprises a top surface 241 and a bottom surface 242. In the exemplified embodiment, the bottom surface 242 is formed from Polytetrafluoroethylene (PTFE). Thus, the septa 240 comprises a main body portion formed from the elastomeric material, and then the PTFE is coated onto the bottom surface of the main body portion. When a liquid sample is located in the bottom portion 209 of the tube cavity 205, the PTFE coated on the bottom surface 242 of the septa 240 faces the liquid sample. The PTFE construction provides superior chemical resistance for broad solvent compatibility and prevents aggressive solvents from compromising the integrity of the closure member 250. The PFE construction also extends component lifetime in challenging chemical environments and maintains sample purity throughout automated handling.

Referring to FIG. 15A, the NMR tube assembly 20 is illustrated in cross-section, showing the septa 240 positioned in the tube cavity 205 of the NMR tube 210 and showing the closure member 250 coupled to the NMR tube 210. As mentioned above, the closure member 250 comprises the head portion 251 and the sleeve portion 252. The closure member 250 comprises a bottom end 253, a top end 254, and a bore 255 that extends through the closure member 250 from the top end 254 to the bottom end 253. The head portion 251 protrudes radially outward from the sleeve portion 252 to define a downwardly facing shoulder 256 that abuts against the top end 202 of the NMR tube 210 when the closure member 250 is coupled to the NMR tube 210.

The bore 255 of the closure member 250 comprises a reservoir chamber 257. The reservoir chamber 257 comprises a funnel section 258 having a taper angle Θ between 55° and 70°, more specifically between 60° and 65°, and still more specifically approximately 63° (approximately including a tolerance of plus or minus 5%). The taper angle Θ may be specifically designed to help guide automated filing needles (needles used to fill the tube cavity 205 with a liquid sample) and create a smooth transition zone for reliable needle penetration. As mentioned above, in one embodiment the closure member 250 is identical to the closure member 150, and as such all descriptions provided herein for the closure member 150 are applicable to the closure member 250 unless a conflicting description is provided here. This applies to the specific details of the bore 255 of the closure member 250, and specifically the reservoir chamber 257 and the funnel section 258.

As mentioned above, in this embodiment the closure member 250 is attached to the NMR tube 210 by inserting the sleeve portion 252 of the closure member 250 into the top portion 208 of the tube cavity 205. The sleeve portion 252 of the closure member 250 comprises an outer surface 259 and an inner surface 260, with the inner surface 260 bounding a part of the bore 255. When the sleeve portion 252 is inserted into the top portion 208 of the tube cavity 205, the outer surface 259 of the sleeve portion 252 comes into direct engagement/contact with the first constriction 220, and more specifically the annular protuberance 232 of the first constriction 220. Thus, the annular protuberance 232 of the first constriction 220 applies a compressive force onto the sleeve portion 252 of the closure member 250 to securely maintain the sleeve portion 252 of the closure member 250 within the tube cavity 205. Thus, the first constriction 220 creates a precise mechanical lock with the sleeve portion 252 of the closure member 250. The first constriction 220 and the sleeve portion 252 may be engineered to have dimensions that ensure optical closure member 250 retention force, to maintain position stability of the closure member 250 relative to the NMR tube 210 during automated handling.

In the exemplified embodiment, the closure member 250 is fully seated on the NMR tube 210 when the top end 202 of the NMR tube 210 abuts against the downwardly facing shoulder 256 formed by the bottom surface of the head portion 251. When so positioned in the exemplified embodiment, the bottom end 253 of the closure member 250 is spaced apart from the septa 240 by a small axial gap. In an embodiment, the closure member 250 and the septa 240 are independently press fit into the NMR tube 210.

Referring to FIG. 15B, the NMR tube assembly 20 is illustrated in cross-section, along with a liquid dispensing device 290 that is dispensing a liquid sample 299 into the bottom portion 209 of the tube cavity 205. In this embodiment, the liquid dispensing device 290 is a syringe or pipette comprising a needle 291. Specifically, for a filling operation, the needle 299 of the liquid dispensing device 290 is inserted through the bore 255 of the closure member 250 and into and through the septa 240. That is, the needle 299 fully penetrates the septa 240 so that the needle 299 extends through the septa 240 until a distal end of the needle 299 is located in the bottom portion 209 of the tube cavity 205. Once so positioned, the liquid dispensing device 290 is activated to dispense the liquid sample 299 into the bottom portion 209 of the tube cavity 205. Once the tube cavity 205 is filled with the liquid sample 299 to the desired volume/height, the needle 299 is pulled back through the septa 240 and removed from the bore 255 of the closure member 250. In some embodiments, the liquid dispensing device 290 may be an automatic dispensing device, such as a liquid handler (as described above) or the like. The NMR tube assembly 20 can be reused and refilled as needed in the same manner.

In an embodiment, the NMR tube assembly 20 fundamentally updates the NMR tube-cap relationship (as compared with traditional/conventional approaches) by creating an integrated internal closure system with precision-engineered glass constrictions and built-in chemical isolation through Polytetrafluoroethylene (PTFE) septa placement. This eliminates the need for manual closure (or cap) manipulation while providing superior chemical resistance and enabling rapid automated sample loading. By moving from external to internal components, the system transforms NMR sample preparation from a manual bottleneck into a streamlined automated process. The two constrictions 220, 230 work together to enable both mechanical stability and chemical isolation due to their engagement with the septa 240 and the closure member 250. The specific shape of the bore 255, including the taper angle of the funnel section 258 presents an optimized cone angle guide for automated filling needles, enhances tolerance for robotic position variation, reduces risk of needle damage during high-speed operations, and creates a smooth transition zone for reliable needle penetration. The dimensions of the components permit exact matching between the septa 240 and NMR tube 210 and between the closure member 250 and the NMR tube 210. The integrated sleeve portion 252 of the closure member 250 works with the first constriction 220 to form a mechanical lock, maintains consistent position during automated handling, and provides a stable platform for repeated needle penetration.

The NMR tube assembly 20 is configured for use in automated and high throughput situations. The integrated system enables fully automated sample preparation while maintaining sample integrity. The assembly allows for high-speed operation through complete elimination of manual closure member 250 removal/replacement, rapid needle guidance through tapered design within the closure member 250, and reduced cycle time for sample loading. The assembly is reliable in that it has a fixed septa 240 positioning that ensures consistent needle penetration, an integrated needle guidance system that reduces positioning errors, and chemical isolation (via the septa 240) that protects the closure member 250 from harsh solvents. Sample quality maintenance is achieved with minimized exposure to environmental contaminants, consistent sample volumes through mechanical design, chemical isolation that prevents sample degradation, and a reduced risk of cross-contamination.

The NMR tube assembly 20 represents an advancement in NMR sample handling technology, particularly in modern high-throughput automated environments. By combining internal closure member/cap design, precision glass engineering, and chemical isolation into a single integrated system, the NMR tube assembly 20 eliminates manual handling requirements while maintaining sample integrity and protecting against aggressive solvents. The result is a comprehensive solution that transforms NMR sample preparation from a manual bottleneck into a streamlined automated process, meeting the demands of contemporary analytical chemistry workflows.

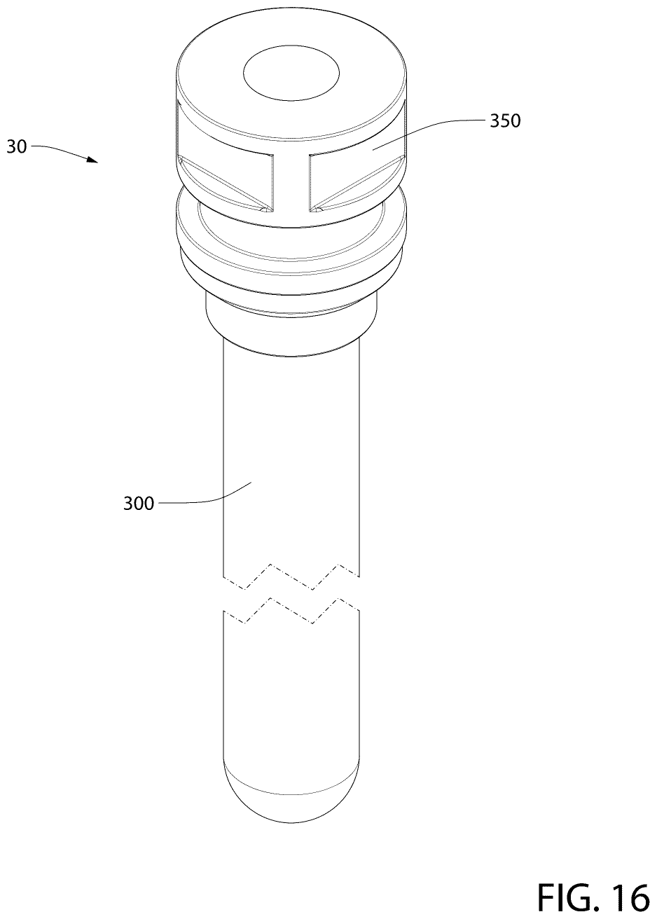

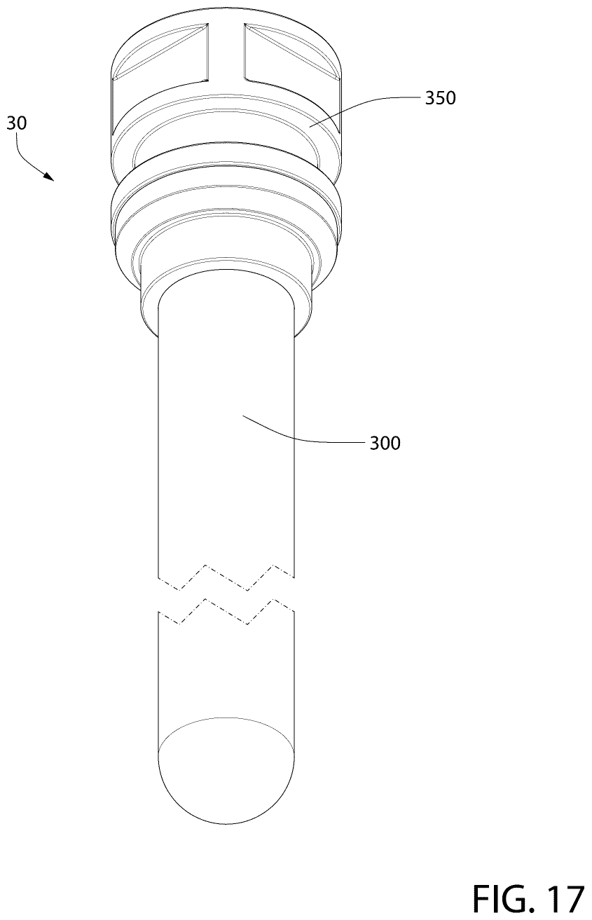

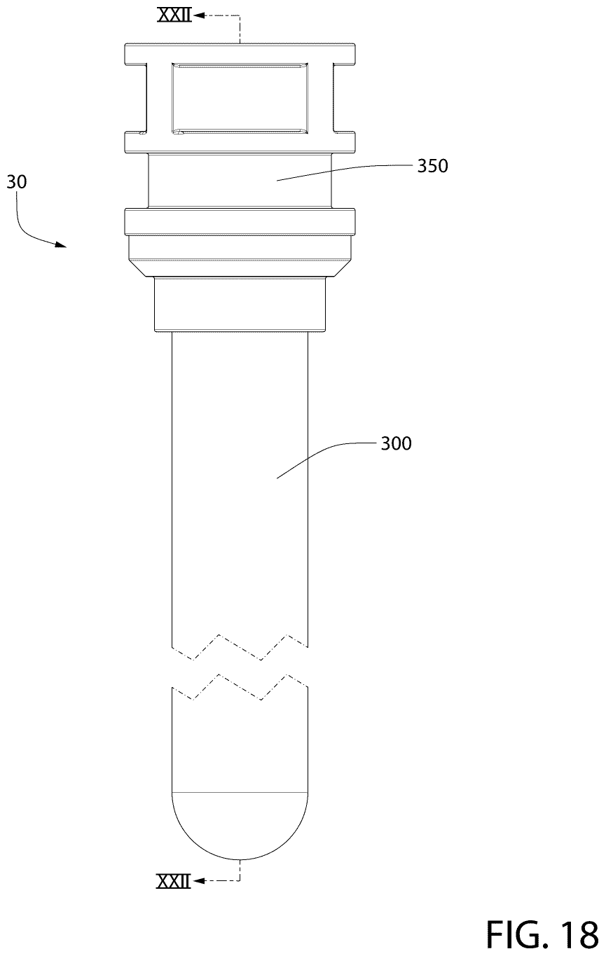

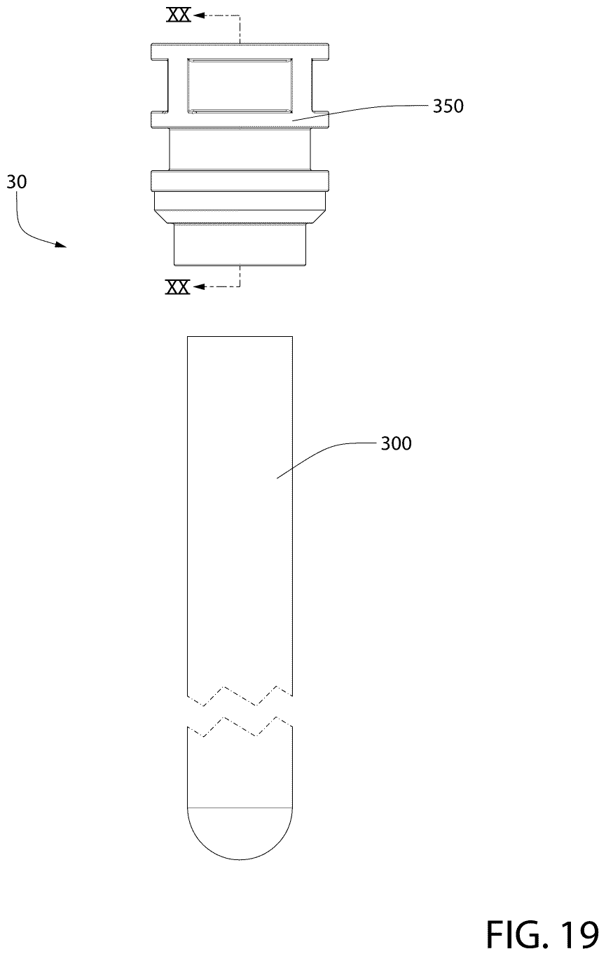

Referring to FIGS. 16-19, an NMR tube assembly 30 is illustrated in accordance with another embodiment of the present invention. The NMR tube assembly 30 generally comprises an NMR tube 300 and a closure assembly 350 that is configured to be attached to the NMR tube 300. In this embodiment, the closure assembly 350 is configured to be attached to an exterior of the NMR tube 300, such that a top portion of the NMR tube 300 is received within a cavity of the closure member assembly.

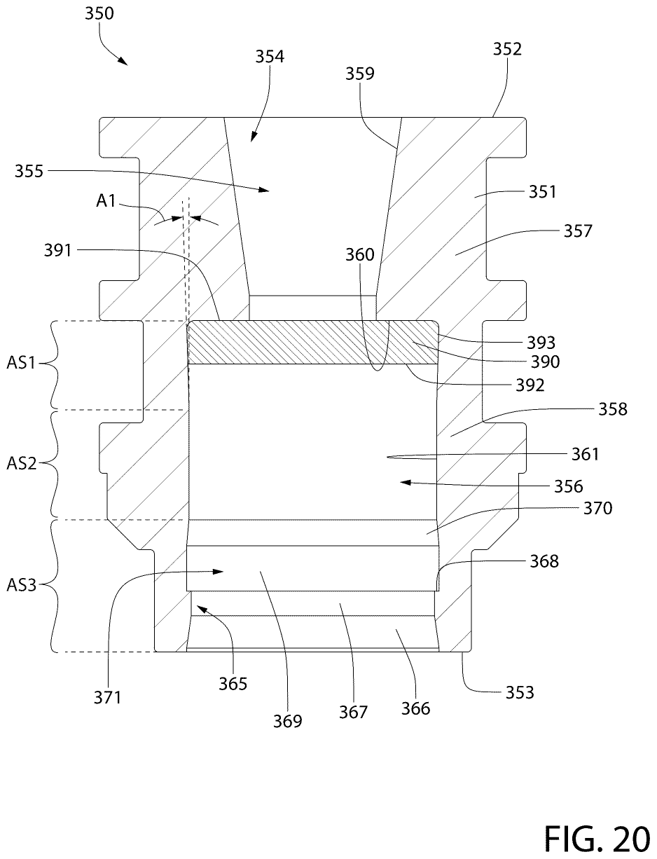

Referring to FIG. 20, the closure assembly 350 will be described in more detail. The closure assembly 350 generally comprises a closure member 351 and a septa 390 that is coupled to the closure member 351. In some embodiments, it may be possible to separate the septa 390 from the closure member 351 by applying a force onto the septa 390 relative to the closure member 351. However, in general the septa 390 and the closure member 351 form an integral structure (i.e., the closure assembly 350) that is configured to be attached to the NMR tube 300 and possibly detached from the NMR tube 300 as a unit.

The closure member 351 comprises a top surface 352, a bottom surface 353, and a bore 354 that extends from the top surface 352 to the bottom surface 353. Thus, the bore 354 extends through the full height of the closure member 351 from an opening in the top surface 352 to an opening in the bottom surface 353. The closure member 351 comprises an upper portion 357 that comprises the top end 352 and a lower portion 358 that comprises the bottom end 353. In the exemplified embodiment, the bore 354 comprises a funnel section 355 located in the upper portion 357 and a relief cavity 356 located in a lower portion 358. Thus, the funnel section 355 comprises the opening in the top end 352 and the relief cavity 356 comprises the opening in the bottom end 353.

The funnel section 355 of the bore 354 is bounded by an inner surface 359 that is tapered such that the funnel section 355 tapers moving from the opening in the top end 352 towards the relief cavity 356. Thus, the funnel section 355 is in the shape of an upside-down truncated cone. The relief cavity 356 is a cavity formed into the bottom end 353 that extends axially (between the bottom end 353 and the top end 352) from the opening in the bottom end 353 to a floor 360 that is located in between the top and bottom ends 352, 353. That is an opening in the floor that extends from the relief cavity 356 to the funnel section 355. The relief cavity 356 can be conceptually divided into a first axial section AS1 that comprises the floor 360, a second axial section AS2 adjacent to the first axial section AS1, and a third axial section AS3 that comprises the opening in the bottom end 353. The second axial section AS2 is axially in between the first and third axial sections AS1, AS3 (axially being the direction between the top and bottom ends 352, 353). Each of the axial sections is a section that includes some part of the length of the relief cavity 356 as measured from the opening in the bottom end 353 of the closure member 351 to the floor 360.

The relief cavity 356 is bounded by an inner surface 361 and the floor 360. Within the first axial section AS1 of the relief cavity 356, the inner surface 361 is tapered (i.e., has a taper angle A1 defined between the inner surface 361 of the first axial section AS1 and a vertical axis) outwardly moving from the second axial section AS2 to the floor 360. That is, the inner surface 361 diverges in a direction towards the top end 352 within the first axial section AS1. In some embodiments, the inner surface 361 is tapered between 1° and 10°, more specifically between 1° and 5°, and more specifically between 1° and 3° within the first axial section AS1. Thus, the taper angle A1 is rather small, but it is sufficient to achieve its purpose of holding the septa 390 in place, as described below.

In the exemplified embodiment, the septa 390 is coupled to the closure member 351 within the first axial section AS1 of the relief cavity 356. The septa 390 comprises a top surface 391, a bottom surface 392, and a peripheral edge 393 between the top and bottom surfaces 391, 392. In the exemplified embodiment, the septa 390 has a disk-like shape, with flat/planar top and bottom surfaces 391, 392. The septa 390 is positioned in the first axal section AS1 of the relief cavity 356 so that the peripheral edge 393 of the septa 390 abuts the inner surface 361 of the relief cavity 356 within the first axial section AS1 of the relief cavity 356. Due to the tapered nature of the inner surface 361 of the relief cavity 356 within the first axial section AS1, a tight-fit is achieved between the inner surface 361 and the septa 390 to secure the septa 390 in position. This prevents the septa 390 from being removed from the relief cavity 356 such as by falling through the bottom end 353 of the closure member 350 when being penetrated by a needle. The tapered nature of the walls will hold the septa 390 tightly in place within the first axial section AS1 of the relief cavity 356.

Thus, the first axial section AS1 of the relief cavity 356 forms a dedicated septa retention space that is integrated directly into the design of the closure member 351, which provides precise dimensional control of the positioning and compression of the septa 390 without the need for additional retention components or adhesives. The septa 390 is held in place by friction/interference fit/compression between the peripheral edge 393 of the septa 390 and the inner surface 356 of the relief cavity 356. This represents a significant advancement over traditional septa retention methods. By incorporating the septa holding feature directly into the closure member 351 architecture, the design achieves several improvements, including more consistent septa positioning, better control over compression forces, enhanced reliability during multiple use cycles, and improved septa stability during needle penetration. In an embodiment, when a needle penetrates the septa 390 during liquid sample dispensing, the tapering of the inner surface 361 which engages the septa 390 will securely hold the septa 390 in place and prevent the septa 390 from moving axially within the relief cavity 356.

As with the prior embodiment, the septa 390 may be formed from an elastomeric material (e.g., silicone), and the bottom surface 392 of the septa 390 that is configured to face the liquid sample may be coated with PTFE. Thus, the description of the materials of the septa 240 described with reference to the previous embodiment are applicable in accordance with embodiments of the present invention. In the exemplified embodiment, a central portion of the top surface 391 of the septa 390 is visible through the opening in the top end 352 of the closure member 351 and through the funnel section 355 of the bore 354.

In the exemplified embodiment, the second axial section AS2 of the relief cavity 356 is cylindrical, with the inner surface 361 being parallel to the longitudinal axis of the closure member 351 in the second axial section AS2. The invention is not to be so limited in all embodiments and the inner surface 361 within the second axial section AS2 may be tapered towards the top send 352 or towards the bottom end 353 in alternative embodiments.

In the exemplified embodiment, the third axial section AS3 of the relief cavity 356 comprises a locking feature 365. The inner surface 361 of the closure member 351 that defines the relief cavity 356 forms the locking feature 365. Specifically, within the third axial section AS3 and moving in a direction from the bottom end 353 towards the second axial section AS2, the inner surface 361 comprises a first tapered portion 366 located immediately adjacent to the bottom end 353, a first straight portion 367 adjacent to the first tapered portion 366, a shoulder 368 adjacent to the first straight portion 367, a second straight portion 369 adjacent to the shoulder 368, and a second tapered portion 370 adjacent to the second straight portion 369. The first and second tapered portions 366, 370 taper inwardly with distance from the bottom end 353. The shoulder 368 is located between the first and second straight portions 367, 369. The shoulder 368 faces upwardly towards the floor 360 of the relief cavity 356. In the exemplified embodiment the shoulder 368 is perpendicular to the first and second straight portions 367, 368. The shoulder 368 forms a sort of hook or engaging feature that is configured to engage with a locking feature on the NMR tube 300 to form a slight locking engagement between the closure member 351 and the NMR tube 300 to keep the closure member 351 securely attached to the NMR tube 300 during handling and processing. The second straight portion 368 forms a receiving pocket 371 for receiving a locking feature of the NMR tube 300, as described further below. Additional details regarding the locking feature 365 of the closure member 351 may be found in U.S. Pat. No. 11,714,144, the entirety of which is incorporated herein by reference.

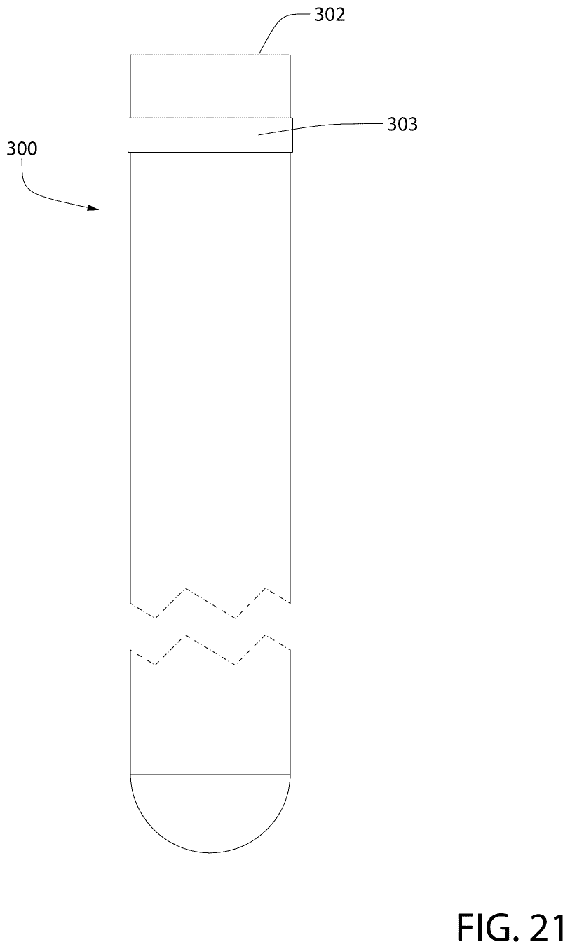

Turning now to FIG. 21, the NMR tube 300 is illustrated in accordance with an embodiment of the present invention. The NMR tube 300 has a bottom end 301, a top end 302, and an outer surface 303. The NMR tube 300 comprises a locking feature 330 on the outer surface 303 adjacent to but spaced apart from the top end 302. In the exemplified embodiment, the locking feature 330 is a ring-shaped locking feature formed on the outer surface 303 of the NMR tube 300. In the exemplified embodiment, the locking feature 330 is a continuous ring-shaped feature. In other embodiments, the locking feature 330 may comprise several spaced apart features that are arranged in a ring-like shape. In an embodiment, the locking feature 330 may be formed by depositing a material onto the outer surface 303 of the NMR tube 300. For example, the locking feature 330 may be formed by depositing an ink-based material on the outer surface 303 of the NMR tube 300. In an embodiment, the material deposited on the outer surface 303 of the NMR tube 300 may comprises an epoxy based screen printing ink, from 70 to 97% w/w; a catalyst, from 3 to 10% w/w; and a silica filler, from 0 to 20% w/w. In yet other embodiments, the epoxy based screen printing ink comprises about 93.8% w/w; the catalyst comprises about 3.6% w/w; and the silica filler comprises about 2.6% w/w. Further details regarding the material that may be used to form the locking feature 330 on the outer surface 303 of the NMR tube 300 is provided in U.S. Pat. No. 11,714,144 , the entirety of which is incorporated herein by reference.

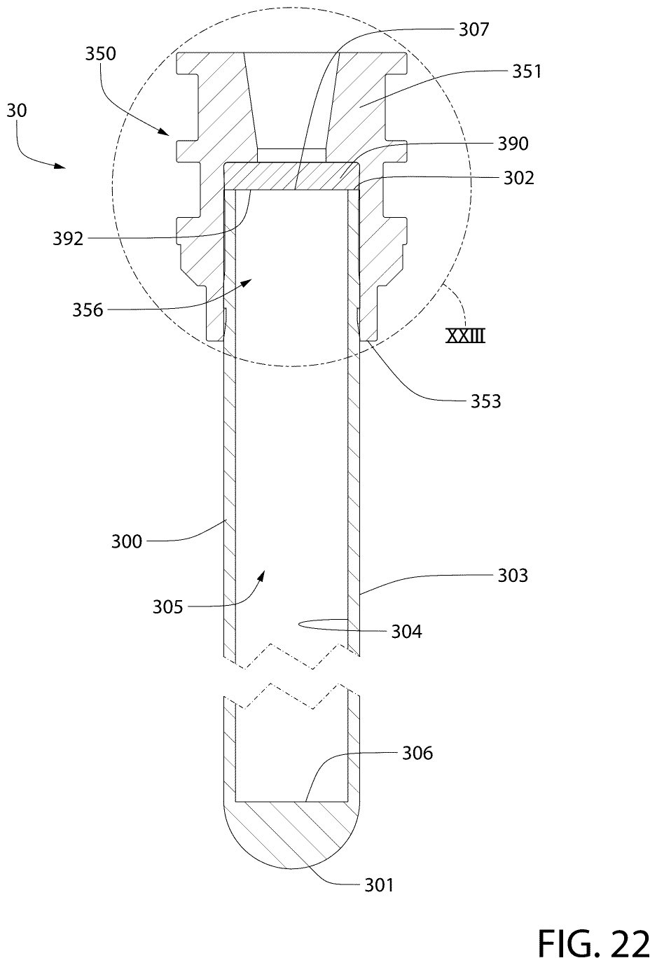

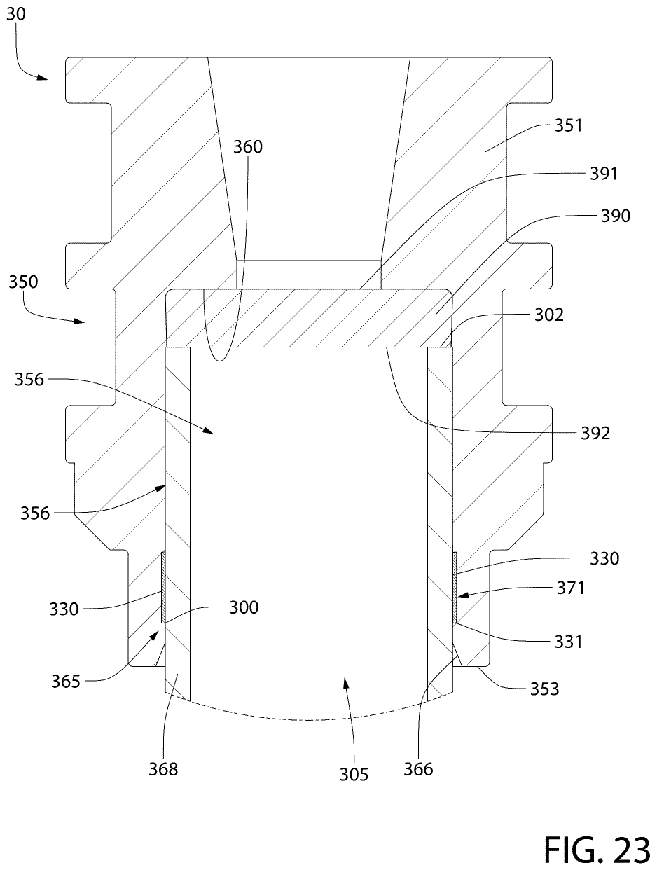

Referring to FIGS. 22 and 23, the NMR tube assembly 30 comprising the NMR tube 300 and the closure assembly 350 will be described. As noted above, the closure assembly 350 comprises the closure member 351 and the septa 390 that is coupled to the closure member 351 within the relief cavity 356. The septa 390 and the closure member 351 are separate components, but they are coupled together to form the closure assembly 350 which is a unitary structure that is configured to be attached to the NMR tube 300. The NMR tube 300 comprises the bottom end 301, the top end 302, and the outer surface 303 as previously described. The NMR tube 300 further comprises an inner surface 304 that defines a tube cavity 305 having a closed bottom end 306 and an open top end 307.

The closure assembly 350 is coupled to the NMR tube 300 by inserting a top portion of the NMR tube 300 through the opening in the bottom end 353 of the closure member 351 and into the relief cavity 356. The closure assembly 350 is moved downwardly along the top portion of the NMR tube 300 until the top end 302 of the NMR tube 300 abuts against the bottom surface 292 of the septa 390. When so positioned, the septa 390 is sandwiched and perhaps compressed between the top end 302 of the NMR tube 300 and the floor 360 of the relief cavity 356 of the closure member 351.

Furthermore, as discussed above, the closure member 351 comprises the locking feature 365 and the NMR tube 300 comprises the locking feature 330. The locking feature 365 of the NMR tube 300 is configured to engage with the locking feature 330 of the NMR tube 300 to lock the position of the closure assembly 350 axially relative to the NMR tube 300. That is, once the closure assembly 350 is fully seated on the NMR tube 300 with the top end 302 of the NMR tube 300 in contact with the bottom surface 392 of the septa 390, the locking feature 365 of the closure member 351 is in engagement with the locking feature 330 of the NMR tube 300.

More specifically, as the closure assembly 350 is pressed onto the top portion of the NMR tube 300, the first tapered portion 366 of the inner surface 361 slides past the locking feature 330 on the NMR tube 300. The closure assembly 350 continues to be pressed onto the top portion of the NMR tube 300 and moved axially downward relative to the NMR tube 300 until the shoulder 368 passes the locking feature 330 and is in engagement with a bottom edge 331 of the locking feature 330. At this point, the locking feature 330 of the NMR tube 300 is located within the receiving pocket 371 of the closure member 351. The engagement between the shoulder 368 of the closure member 351 and the bottom edge 331 of the locking feature 330 axially locks the closure assembly 350 to the NMR tube 300. The closure assembly 350 can still be separated from the NMR tube 300, but a force sufficient to disengage the shoulder 368 from the locking feature 330 is required to do so. Thus, the closure assembly 350 will not become accidentally disengaged from the NMR tube 300. Furthermore, the engagement between the locking feature 330 of the NMR tube 300 and the locking feature 365 of the closure member 351 is sufficient to retain the closure member 351 attached to the NMR tube 300 during normal handling by a user or robot.

In the exemplified embodiment, the NMR tube 300 and the closure assembly 350 are devoid of any threads to facilitate the attachment of the two components to one another. Rather, the closure member 350 is press-fit onto the NMR tube 300 as described above, and the two parts are locked together due to the engagement of the corresponding locking features 330, 365 thereof.

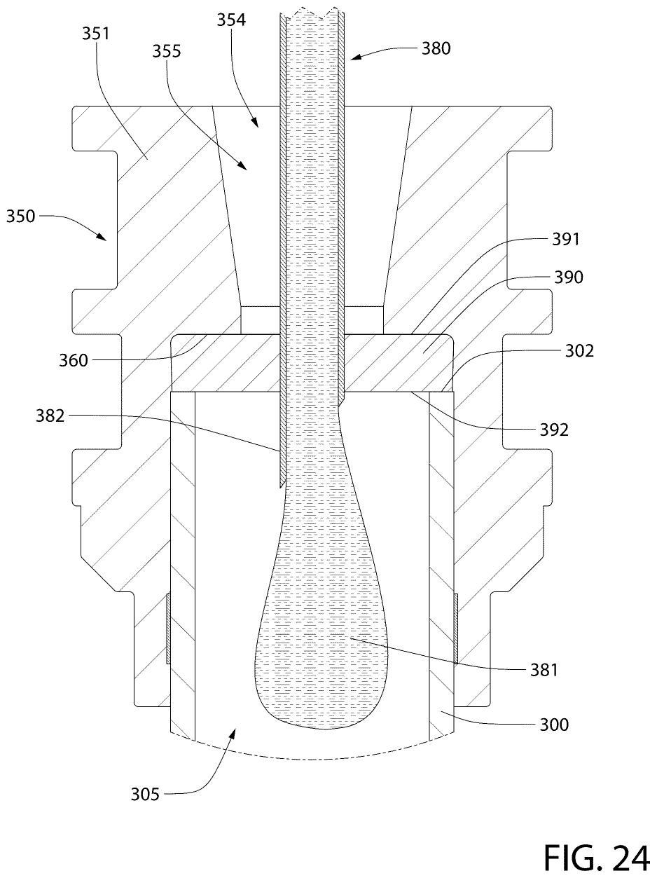

Referring to FIG. 24, a detail view is provided illustrating the closure assembly 350 attached to the top portion of the NMR tube 350, and further illustrating a liquid dispensing device 380 dispensing a liquid sample 381 into the tube cavity 305 of the NMR tube 300. In the exemplified embodiment, the liquid dispensing device 380 may be a syringe or a pipette with a needle. In some embodiments, the liquid dispensing device 380 is an automatic liquid handler, such as those described herein above with reference to earlier described embodiments. Thus, the liquid dispensing device 380 may be operated manually by an operator or automatically/robotically.

As shown in FIG. 24, the needle of the liquid dispensing device 380 is inserted through the funnel section 355 of the bore and then into and through the septa 390 so that at least a distal end 382 of the needle of the liquid dispensing device 380 penetrates through the septa 390 and is positioned within the tube cavity 305 of the NMR tube 300. In some embodiments, the distal end 382 of the needle 382 may be inserted further into the tube cavity 305 towards the bottom end 306 (see FIG. 22) of the tube cavity 305 prior to dispensing the liquid sample, with the needle being withdrawn during the dispensing as described previously. Because the septa 390 is sandwiched between the top end 302 of the NMR tube 300 and the floor 360 of the relief cavity 356, the septa 390 remains in place even while the needle of the liquid dispensing device 380 is inserted into and removed from the tube cavity 305. While the needle of the liquid dispensing device 380 is located within the tube cavity 305, the liquid dispensing device 380 dispenses the liquid sample 381 into the tube cavity 305 of the NMR tube 300. After completing the dispensing of the liquid sample 381, the needle of the liquid dispensing device 380 is removed from the tube cavity 305 and pulled back through the septa 390.

The NMR tube assembly 30 described eliminates the need for glass fusion or threading by incorporating the septa 390 directly into the closure member 350. Using these techniques, consistent septa 390 positioning is achieved and maintained during repeated needle penetrations. Reliable sealing of the tube cavity 305 is ensured through engineered compression zones. Furthermore, the NMR tube assembly 30 is configured to be used (i.e., compatible) with existing automated sample changers, such as for example without limitation the Bruker® SampleJet. The NMR tube assembly can then be integrated into high-throughput workflows using standardized handling protocols.

While the invention has been described with respect to specific examples including presently preferred modes of carrying out the invention, those skilled in the art will appreciate that there are numerous variations and permutations of the above described systems and techniques. It is to be understood that other embodiments may be utilized and structural and functional modifications may be made without departing from the scope of the present invention. Thus, the spirit and scope of the invention should be construed broadly as set forth in the appended claims.

1. A method for loading liquid samples into NMR tubes, the method comprising:
attaching one of a plurality of closures to each of a plurality of NMR tubes to form a plurality of NMR tube assemblies;
introducing a liquid sample into a reservoir chamber of each of the plurality of closures of each of the plurality of NMR tube assemblies, the liquid sample being maintained in the reservoir chamber of the closure without passively flowing into a cavity of the NMR tube to which the closure is attached; and
subjecting the plurality of NMR tube assemblies to a centrifugal force to transfer the liquid sample from the reservoir chamber of the closure into the cavity of the NMR tube to which the closure is attached.

2. The method according to claim 1 wherein the reservoir chamber of each of the plurality of closures comprising a tapered funnel section having a taper angled between 55° and 70°.

3. The method according to claim 1 further comprising:
prior to subjecting the plurality of NMR tubes to the centrifugal force, positioning the plurality of NMR tube assemblies in a tube rack; and
placing the tube rack in a centrifuge and activating the centrifuge to generate the centrifugal force to transfer the liquid sample from each of the plurality of closures into each respective one of the plurality of NMR tubes.

4. The method according to claim 1 further comprising:
prior to introducing the liquid sample into the reservoir chamber of the plurality of closures, positioning the plurality of NMR tube assemblies in a tube rack; and
while the plurality of NMR tube assemblies are held in the tube rack, introducing the liquid sample into the reservoir chamber of the plurality of closures, and then subjecting the tube rack and the plurality of NMR tube assemblies held in the tube rack to the centrifugal force.

5. The method according to claim 4 further comprising:
introducing the liquid sample into the reservoir chamber of multiple of the plurality of closures simultaneously using a liquid dispensing device.

6. The method according to claim 5 wherein the liquid dispensing device is a multi-channel liquid handler configured to fill the reservoir chamber of the multiple of the plurality of closures with the liquid sample simultaneously.

7. The method according to claim 5 wherein the liquid dispensing device is configured to introduce the liquid sample into the reservoir chamber of the multiple of the plurality of closures without any portion of the liquid dispensing device entering the reservoir chamber.

8. The method according to claim 3 wherein the tube rack is configured to hold at least 96 of the NMR tube assemblies.

9. The method according to claim 1 wherein the centrifugal force is applied by a centrifuge operating at 1500-2500 relative centrifugal force (RCF).

10. The method according to claim 1 wherein after the plurality of NMR tube assemblies are subjected to the centrifugal force, the liquid sample is transferred to the cavity of the NMR tube to which the closure is attached and the liquid sample in the cavity of the NMR tube is bubble-free.

11. The method according to claim 1 further comprising:
each of the plurality of NMR tubes having an inner diameter of either approximately 0.7 mm or approximately 1.3 mm;
each of the plurality of closures having an opening that forms a passageway into the reservoir chamber, wherein the liquid sample is introduced into the reservoir chamber through the opening, and wherein the opening has a diameter between 3.2 mm and 3.7 mm.

12. A method for loading a liquid sample into an NMR tube, the method comprising:
attaching a closure to an NMR tube to form an NMR tube assembly, the closure comprising a reservoir chamber and the NMR tube having a cavity;
introducing a liquid sample into the reservoir chamber of the closure of the NMR tube assembly, the liquid sample being maintained in the reservoir chamber of the closure and being prevented from passively flowing into the cavity of the NMR tube to which the closure is attached; and
subjecting the NMR tube assembly to a centrifugal force to transfer the liquid sample from the reservoir chamber of the closure into the cavity of the NMR tube.

13. The method according to claim 12 wherein the NMR tube has a top end having an opening, and wherein the reservoir chamber of the closure is located upstream of the opening of the NMR tube when the closure is attached to the NMR tube.

14. The method according to claim 12 wherein the closure has an opening that forms a passageway into the reservoir chamber, the opening of the closure having a diameter between 3.2 mm and 3.7 mm, and wherein the cavity of the NMR tube has a diameter of either approximately 0.7 mm or approximately 1.3 mm.

15. The method according to claim 12 further comprising:
prior to introducing the liquid sample into the reservoir chamber of the closure of the NMR tube assembly, placing the NMR tube assembly in a tube rack;
introducing the liquid sample into the reservoir chamber of the closure of the NMR tube assembly while the NMR tube assembly is located in the tube rack;
positioning the tube rack in a centrifuge; and
activating the centrifuge to subject the NMR tube assembly to the centrifugal force.

16. A closure for an NMR tube, the closure comprising:
a top end having a first opening;
a bottom end having a second opening;
a bore that extends from the first opening in the top end to the second opening in the bottom end, the bore comprising a reservoir chamber located adjacent to the first opening, the reservoir chamber comprising a tapered funnel section having a taper angle between 55° and 70°; and
wherein the closure is configured to be coupled to the NMR tube to form an NMR tube assembly, and wherein a liquid sample received in the reservoir chamber is configured to be held in the reservoir chamber until transferred into the NMR tube by subjecting the NMR tube assembly to a centrifugal force.

17. The closure according to claim 16 further comprising:
a head portion that comprises the first opening and the reservoir chamber; and
a sleeve portion that extends axially from a lower end of the head portion, an inner surface of the sleeve portion forming a sealing interface that is configured to engage with an outer surface of the NMR tube when the closure is coupled to the NMR tube to provide a secure fit and prevent leakage during sample loading and analysis.

18. The closure according to claim 16 further comprising:
the first opening having a first diameter;
the NMR tube to which the closure is configured to be coupled having an inner diameter; and
wherein the first diameter is at least 2.5 times greater than the inner diameter of the NMR tube.

19. The closure according to claim 16 wherein the taper angle is between 60° and 65°.

20. The closure according to claim 16 further comprising:
the reservoir chamber comprising a cylindrical section that extends from the tapered funnel section to the first opening in the top end, the cylindrical section having a constant diameter and the funnel section having a diameter that decreases with increasing distance from the cylindrical section.

21.-56. (canceled)
